(19) United States
(12) Patent Application Publication
(10) Pub. No.: US 2026/0190346 A1
(43) Pub. Date: Jul. 2, 2026

(54) SEMICONDUCTOR MEMORY DEVICE

(71) Applicant: SAMSUNG ELECTRONICS CO., LTD., Suwon-si (KR)

(72) Inventors: Kyunghwan LEE, Suwon-si (KR); Kilho LEE, Suwon-si (KR); Jungpyo HONG, Suwon-si (KR)

(73) Assignee: SAMSUNG ELECTRONICS CO., LTD., Suwon-si (KR)

(21) Appl. No.: 19/437,987

(22) Filed: Dec. 31, 2025

(30) Foreign Application Priority Data
Jan. 2, 2025 (KR) 10-2025-0000455

(51) Int. Cl. H10B 53/20; H10B 53/30

(52) U.S. Cl. CPC H10B 53/20; H10B 53/30

(57) ABSTRACT

A semiconductor memory device includes a substrate, a first conductive line on the substrate, a channel structure on the first conductive line, a gate structure including a gate electrode on the first conductive line and a gate insulating film between the gate electrode and the channel structure, a plurality of second conductive lines on the channel structure and the gate structure, and spaced apart from each other in a vertical direction, a vertical conductive line on the channel structure, extending in the vertical direction, and penetrating the second conductive lines, and a ferroelectric pattern provided between each of the second conductive lines and the vertical conductive line. The vertical conductive line includes a plurality of electrode recesses corresponding to the second conductive lines and extending into the vertical conductive line. Portions of the ferroelectric pattern and portions of the second conductive lines fill each of the electrode recesses.

### CROSS-REFERENCE TO RELATED APPLICATION

This application is based on and claims priority under 35 U.S.C. § 119 to Korean Patent Application No. 10-2025-0000455, filed on Jan. 2, 2025, in the Korean Intellectual Property Office, the disclosure of which is incorporated by reference herein in its entirety.

### BACKGROUND

The present disclosure relates to a semiconductor memory device, and more particularly, to a semiconductor memory device including a ferroelectric capacitor.

As electronic products become more miniaturized, multifunctional, and high-performance, high-capacity semiconductor memory devices are required. In order to provide semiconductor memory devices with high capacity and increased integration, various types of semiconductor memory devices have been researched. For example, semiconductor memory devices including ferroelectric capacitors instead of general capacitors have been proposed.

### SUMMARY

One or more example embodiments provide a semiconductor memory device including a ferroelectric capacitor, which may be capable of increasing a degree of integration and improving reliability.

According to an aspect of the disclosure, a semiconductor memory device includes: a substrate; a first conductive line on the substrate; a channel structure on the first conductive line; a gate structure including a gate electrode on the first conductive line, and a gate insulating film between the gate electrode and the channel structure; a plurality of second conductive lines on the channel structure and the gate structure, and spaced apart from each other in a vertical direction; a vertical conductive line on the channel structure, extending in the vertical direction, and penetrating the plurality of second conductive lines; and a ferroelectric pattern between each of the plurality of second conductive lines and the vertical conductive line, wherein the vertical conductive line includes a plurality of electrode recesses corresponding to the plurality of second conductive lines and extending into the vertical conductive line, and portions of the ferroelectric pattern and portions of the plurality of second conductive lines fill the plurality of electrode recesses.

According to an aspect of the disclosure, a semiconductor memory device includes: a plurality of first conductive lines extending in a first horizontal direction and spaced apart from each other in a second horizontal direction orthogonal to the first horizontal direction; a plurality of channel structures extending in a vertical direction and arranged in columns on the plurality of first conductive lines in each of the first horizontal direction and the second horizontal direction; a plurality of gate structures including a plurality of gate lines on the plurality of first conductive lines, spaced apart from each other in the first horizontal direction, and extending in the second horizontal direction, and a plurality of gate insulating films between the plurality of gate lines and the plurality of channel structures and surrounding at least a portion of side surfaces of the plurality of channel structures; a plurality of second conductive lines on the plurality of channel structures, spaced apart from each other in each of the first horizontal direction and the vertical direction, and extending in the second horizontal direction; a plurality of vertical conductive lines on the plurality of channel structures, extending in the vertical direction, and penetrating the plurality of second conductive lines; and a plurality of ferroelectric patterns between the plurality of second conductive lines and the plurality of vertical conductive lines, wherein each vertical conductive line of the plurality of vertical conductive lines includes a plurality of electrode recesses corresponding to second conductive lines spaced apart from each other in the vertical direction, each vertical conductive line of the plurality of vertical conductive lines penetrates a corresponding conductive line of the plurality of second conductive lines, portions of the plurality of ferroelectric patterns which cover surfaces of the plurality of vertical conductive lines within the plurality of electrode recesses define a plurality of dielectric recesses, and the plurality of second conductive lines includes a plurality of conductive base portions and a plurality of conductive protruding portions that fill the plurality of dielectric recesses.

According to an aspect of the disclosure, a semiconductor memory device includes: a substrate; a plurality of first conductive lines on the substrate, extending in a first horizontal direction, and spaced apart from each other in a second horizontal direction orthogonal to the first horizontal direction; a plurality of channel structures arranged on the plurality of first conductive lines in columns in each of the first horizontal direction and the second horizontal direction, wherein each channel structure of the plurality of channel structures includes a first impurity area, a channel region, and a second impurity area, which are sequentially arranged in a vertical direction, and wherein the first impurity area contacts one of the plurality of first conductive lines; a plurality of gate structures including a plurality of gate lines on the plurality of first conductive lines, spaced apart from each other in the first horizontal direction, and extending in the second horizontal direction, and a plurality of gate insulating films provided between the plurality of gate lines and one of the plurality of channel structures and surrounds at least a portion of a side surface of one of the plurality of channel structures; a plurality of second conductive lines on the plurality of channel structures, spaced apart from each other in each of the first horizontal direction and the vertical direction, and extending in the second horizontal direction; a plurality of vertical conductive lines respectively contacting the second impurity areas, extending in the vertical direction, and penetrating the plurality of second conductive lines; and a plurality of ferroelectric patterns provided between the plurality of second conductive lines and the plurality of vertical conductive lines, wherein each vertical conductive line of the plurality of vertical conductive lines includes a plurality of electrode recesses corresponding to second conductive lines spaced apart from each other in the vertical direction, wherein each vertical conductive line of the plurality of vertical conductive lines penetrates a corresponding second conductive line of the plurality of second conductive lines and extends two-dimensionally, wherein each of plurality of electrode recesses surrounds a corresponding vertical conductive line of the plurality of vertical conductive lines, wherein portions of the plurality of ferroelectric patterns which cover surfaces of the plurality of vertical conductive lines within the plurality of electrode recesses define a plurality of dielectric recesses, and wherein each of the plurality of second conductive lines includes a conductive base portion having a first maximum height, and a conductive protruding portion having a second maximum height greater than the first maximum height and filling a corresponding dielectric recess of the plurality of dielectric recesses.

According to an aspect of the disclosure, a method for manufacturing a semiconductor memory device may include: providing a substrate; providing a first conductive line on the substrate; providing a channel structure on the first conductive line; providing a gate structure including: a gate electrode on the first conductive line; and a gate insulating film between the gate electrode and the channel structure; providing a plurality of second conductive lines on the channel structure and the gate structure, wherein the plurality of second conductive lines are spaced apart from each other in a vertical direction; providing a vertical conductive line on the channel structure, extending in the vertical direction, and penetrating the plurality of second conductive lines; and providing a ferroelectric pattern between each of the plurality of second conductive lines and the vertical conductive line, wherein the vertical conductive line includes a plurality of electrode recesses corresponding to the plurality of second conductive lines and extending into the vertical conductive line, and wherein portions of the ferroelectric pattern and portions of the plurality of second conductive lines fill each of the plurality of electrode recesses.

According to an aspect of the disclosure, the method may further include providing the plurality of electrode recesses wherein each of the plurality of electrode recesses continuously extends two-dimensionally and surrounds the vertical conductive line.

According to an aspect of the disclosure, the method may further include providing the plurality of second conductive lines, wherein each of the plurality of second conductive lines includes a conductive base portion and a conductive protruding portion, wherein the conductive protruding portion fills a respective one of the plurality of electrode recesses, and wherein a maximum height of the conductive protruding portion in the vertical direction is greater than a maximum height of the conductive base portion in the vertical direction.

According to an aspect of the disclosure, the method may further include providing the plurality of electrode recesses wherein each of the plurality of electrode recesses has a concave shape extending into the vertical conductive line.

According to an aspect of the disclosure, the method may further include providing the plurality of second conductive lines wherein each of the plurality of second conductive lines includes a conductive base portion and a conductive protruding portion, wherein the conductive protruding portion fills a corresponding one of the plurality of electrode recesses, and wherein the conductive protruding portion has a convex shape extending into the vertical conductive line.

According to an aspect of the disclosure, the method may further include providing the plurality of electrode recesses wherein each of the plurality of electrode recesses extends into the vertical conductive line with a height uniformly decreasing in the vertical direction.

According to an aspect of the disclosure, the method may further include providing the channel structure and the gate structure wherein the channel structure and the gate structure configure a vertical channel transistor.

According to an aspect of the disclosure, the method may further include providing the plurality of second conductive lines, wherein each of the plurality of second conductive lines includes a pair of sub-conductive lines that are spaced apart from each other in a horizontal direction.

According to an aspect of the disclosure, the method may further include providing the ferroelectric pattern wherein the ferroelectric pattern continuously extends two-dimensionally and surrounds the vertical conductive line.

According to an aspect of the disclosure, the method may further include providing the ferroelectric pattern wherein the ferroelectric pattern extends two-dimensionally along each of side surfaces of the pair of sub-conductive lines, the side surfaces facing the vertical conductive line.

### BRIEF DESCRIPTION OF THE DRAWINGS

The above and other aspects and features will be more apparent from the following detailed description of one or more example embodiments taken in conjunction with the accompanying drawings, in which:

FIG. 1 is an equivalent circuit diagram showing a cell array of a semiconductor memory device according to one or more example embodiments;

FIGS. 2A and 2B are diagrams showing a semiconductor memory device according to one or more example embodiments;

FIGS. 3A, 3B, 4A, 4B, 5A, 5B, 6A, 6B, 7A, 7B, 8A, 8B, 9A, 9B, 10A, 10B, 11A, 11B, 12A and 12B are diagrams showing a method of manufacturing a semiconductor memory device according to a process sequence, according to one or more example embodiments;

FIGS. 13A and 13B are diagrams respectively showing semiconductor memory devices according to one or more example embodiments;

FIGS. 14A, 14B and 14C are each an enlarged view showing a portion of a semiconductor memory device, according to one or more example embodiments;

FIGS. 15A, 15B, 15C and 15D are each an enlarged view showing a portion of a semiconductor memory device, according to one or more example embodiments; and

FIGS. 16A, 16B, 16C and 16D are each an enlarged view showing a portion of a semiconductor memory device, according to one or more example embodiments.

### DETAILED DESCRIPTION

Hereinafter, one or more example embodiments will be described in detail with reference to the accompanying drawings. The same reference numerals are used for the same components in the drawings, and duplicate descriptions thereof are omitted.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

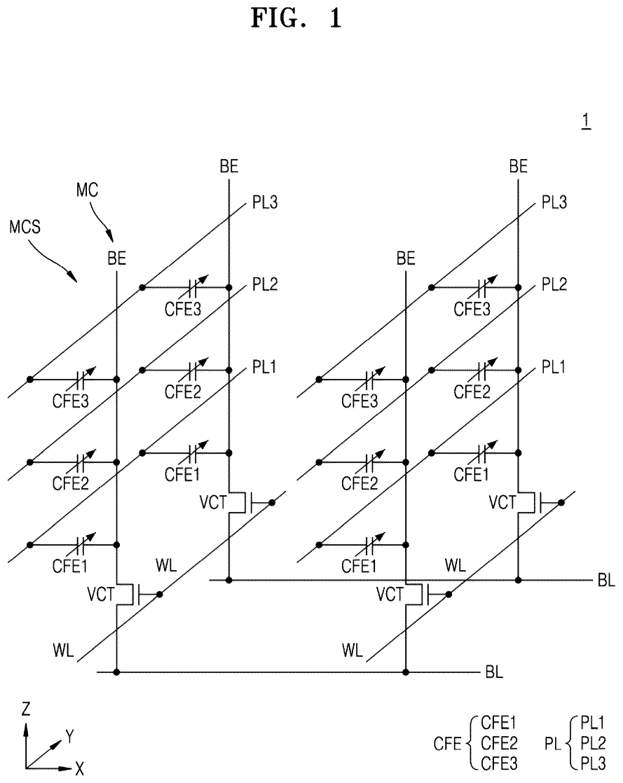

FIG. 1 is an equivalent circuit diagram showing a cell array of a semiconductor memory device 1 according to one or more example embodiments.

Referring to FIG. 1, the semiconductor memory device 1 according to one or more example embodiments may include a cell array MCS including a plurality of memory cells MC. The plurality of memory cells MC may be arranged in columns and rows along a first horizontal direction (X direction) and a second horizontal direction (Y direction) that is a different direction from the first horizontal direction (X direction). In one or more example embodiments, the second horizontal direction (Y direction) may be orthogonal to the first horizontal direction (X direction). In one or more example embodiments, the second horizontal direction (Y direction) may be a direction extending by forming an acute angel with the first horizontal direction (X direction).

Each of the plurality of memory cells MC may include a transistor and a plurality of capacitors. In one or more example embodiments, each of the plurality of memory cells MC may be a 1 Transistor n Capacitor (1TnC) memory including one transistor and a plurality of capacitors. Each of the plurality of capacitors in the memory cell MC may be a ferroelectric capacitor. For example, each of the plurality of memory cells MC may be a 1 Transistor n FErroelectric Capacitor (1TnCFE) memory cell including one transistor and a plurality of ferroelectric capacitors, and a semiconductor memory device having the cell array MCS including the plurality of memory cells MC may be referred to as 1 Transistor n Capacitor ferroelectric random-access memory (1TnC FeRAM). In one or more example embodiments, each of the plurality of memory cells MC may be a 2 Transistor n Capacitor (2TnC) memory cell including two transistors and a plurality of capacitors, or a 3 Transistor n Capacitor (3TnC) memory cell including three transistors and a plurality of capacitors. For example, each of the plurality of memory cells MC may be a 2 Transistor n FErroelectric Capacitor (2TnCFE) memory cell including two transistors and a plurality of ferroelectric capacitors, or a 3 Transistor n FErroelectric Capacitor (3TnCFE) memory cell including three transistors and a plurality of ferroelectric capacitors.

Each of the plurality of memory cells MC may include a vertical channel transistor VCT and a plurality of ferroelectric capacitors (CFE), but embodiments of the disclosure are not limited thereto. For example, each of the plurality of memory cells MC may include, instead of the vertical channel transistor VCT, a planar transistor, a recess-channel array transistor (RCAT), a buried-channel cell array transistor (BCAT), a fin field effect transistor (FinFET), or a gate-all-around (GAA) transistor. The plurality of ferroelectric capacitors CFE in the memory cell MC may be arranged to be stacked with the vertical channel transistor VCT in a vertical direction (Z direction). The plurality of ferroelectric capacitors CFE may be arranged above the vertical channel transistor VCT, but embodiments of the disclosure are not limited thereto. For example, the plurality of ferroelectric capacitors CFE may be arranged under the vertical channel transistor VCT.

In one or more example embodiments, the vertical channel transistor VCT and the plurality of ferroelectric capacitors CFE may be sequentially arranged in the vertical direction (Z direction). For example, the semiconductor memory device 1 may be formed by forming, on a peripheral circuit, the vertical channel transistor VCT and the plurality of ferroelectric capacitors CFE sequentially in the vertical direction (Z direction), or by forming a first structure in which the vertical channel transistor VCT and the plurality of ferroelectric capacitors CFE are sequentially arranged in the vertical direction (Z direction) and then bonding the first structure to a second structure including a peripheral circuit. In one or more example embodiments, the plurality of ferroelectric capacitors CFE and the vertical channel transistor VCT may be sequentially arranged in the vertical direction (Z direction). For example, the semiconductor memory device 1 may be formed by forming a first structure in which the vertical channel transistor VCT and the plurality of ferroelectric capacitors CFE are sequentially arranged in the vertical direction (Z direction) and then flipping and bonding the first structure to a second structure including a peripheral circuit.

Each of the plurality of ferroelectric capacitors CFE in one memory cell MC may be arranged in the vertical direction (Z direction). FIG. 1 illustrates that one memory cell MC includes three ferroelectric capacitors CFE including a first ferroelectric capacitor CFE1, a second ferroelectric capacitor CFE2, and a third ferroelectric capacitor CFE3, but this is an example, and embodiments of the disclosure are not limited thereto. For example, one memory cell MC may include four or more ferroelectric capacitors CFE.

A bit line BL may be connected to a source of the vertical channel transistor VCT, a word line WL may be connected to a gate thereof, and a lower electrode BE of the plurality of ferroelectric capacitors CFE may be connected to a drain. The lower electrode BE may be connected to one end of each of the plurality of ferroelectric capacitors CFE, and each of a plurality of power lines PL may be connected to the other end of each of the plurality of ferroelectric capacitors CFE. The plurality of power lines PL may include a plurality of first power lines PL1, a plurality of second power lines PL2, and a plurality of third power lines PL3. FIG. 1 illustrates that one memory cell MC includes three power lines PL including the first power line PL1, the second power line PL2, and the third power line PL3, however, this is as an example, and embodiments of the disclosure are not limited thereto. For example, one memory cell MC may include four or more power lines PL. In one or more example embodiments, the number of the power lines PL arranged in the vertical direction (Z direction) may be the same as the number of the plurality of ferroelectric capacitors CFE in one memory cell MC.

For example, when one memory cell MC includes the three ferroelectric capacitors CFE that include the first ferroelectric capacitor CFE1, the second ferroelectric capacitor CFE2, and the third ferroelectric capacitor CFE3, the first power line PL1, the second power line PL2, and the third power line PL3 may be respectively connected to the other ends of the first ferroelectric capacitor CFE1, the second ferroelectric capacitor CFE2, and the third ferroelectric capacitor CFE3. The plurality of ferroelectric capacitors CFE may be connected in parallel to the lower electrode BE.

The memory cell MC may be selected by the vertical channel transistor VCT, and reading, writing, or erasing of information with respect to the memory cell MC may be selected by the bit line BL and the word line WL.

The plurality of bit lines BL may extend in the first horizontal direction (X direction) while being spaced apart from each other in the second horizontal direction (Y direction). The plurality of word lines WL may extend in the second horizontal direction (Y direction) while being spaced apart from each other in the first horizontal direction (X direction).

The first power line PL1, the second power line PL2, and the third power line PL3 may be spaced apart from one another in the vertical direction (Z direction) and may be sequentially arranged. The plurality of first power lines PL1 may extend in the first horizontal direction (X direction) and the second horizontal direction (Y direction). The plurality of second power lines PL2 may extend in the first horizontal direction (X direction) and the second horizontal direction (Y direction). The plurality of third power lines PL3 may extend in the first horizontal direction (X direction) and the second horizontal direction (Y direction). The plurality of lower electrodes BE may extend in the vertical direction (Z direction) while being spaced apart from each other in each of the first horizontal direction (X direction) and the second horizontal direction (Y direction). For example, the plurality of lower electrodes BE may extend in the vertical direction (Z direction) while forming columns in each of the first horizontal direction (X direction) and the second horizontal direction (Y direction).

The plurality of power lines PL may be connected to the plurality of ferroelectric capacitors CFE of each of the plurality of memory cells MC, which are arranged in columns and rows along the first horizontal direction (X direction) and the second horizontal direction (Y direction). For example, the first power line PL1 may be connected to the first ferroelectric capacitor CFE1 of each of the plurality of memory cells MC, which are arranged in columns and rows along the first horizontal direction (X direction) and the second horizontal direction (Y direction), the second power line PL2 may be connected to the second ferroelectric capacitor CFE2 of each of the plurality of memory cells MC, which are arranged in columns and rows along the first horizontal direction (X direction) and the second horizontal direction (Y direction), and the third power line PL3 may be connected to the third ferroelectric capacitor CFE3 of each of the plurality of memory cells MC, which are arranged in columns and rows along the first horizontal direction (X direction) and the second horizontal direction (Y direction).

Each of the plurality of ferroelectric capacitors CFE may have a positive polarization and a negative polarization. The voltage applied to the gate of the vertical channel transistor VCT may vary depending on the polarization direction of each of the plurality of ferroelectric capacitors CFE included in one memory cell MC. For example, when one memory cell MC includes the first ferroelectric capacitor CFE1, the second ferroelectric capacitor CFE2, and the third ferroelectric capacitor CFE3, there may be four states of three positive polarizations, two positive polarizations and one negative polarization, one positive polarization and two negative polarizations, and three negative polarizations, so that one memory cell MC may store 2-bit information. When the number of the plurality of ferroelectric capacitors CFE included in one memory cell MC is increased, one memory cell MC may store 3-bit or more information.

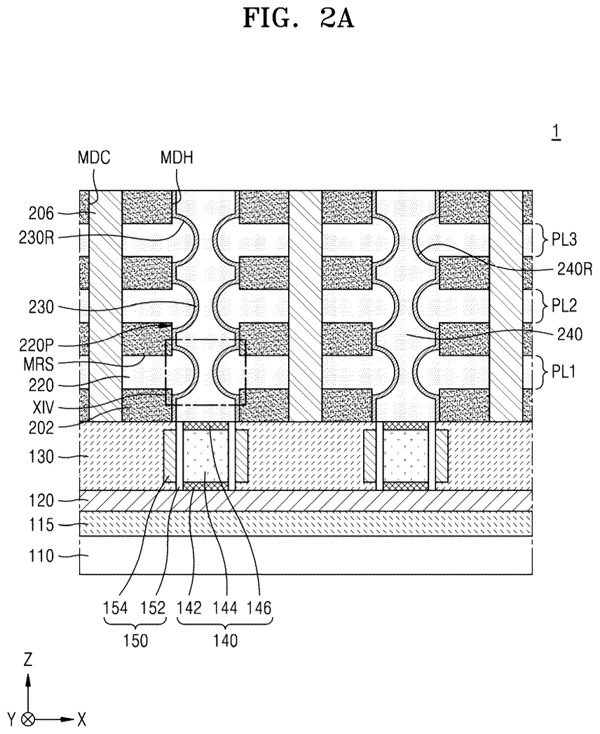

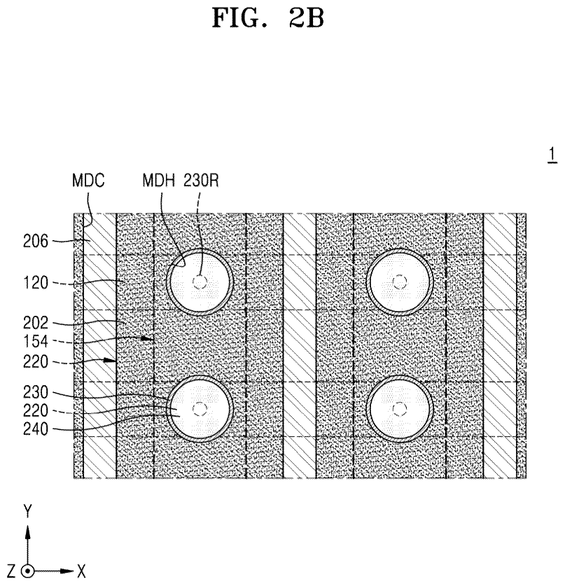

FIGS. 2A and 2B are diagrams showing the semiconductor memory device 1 according to one or more example embodiments. In detail, FIG. 2A is a vertical cross-sectional view of the semiconductor memory device 1 cut in the first horizontal direction (X direction) along a plurality of vertical conductive lines 240 included in the semiconductor memory device 1, and FIG. 2B is a plan view of the semiconductor memory device 1 viewed from the top.

Referring to FIGS. 2A and 2B together, according to one or more example embodiments, the semiconductor memory device 1 may include a substrate 110, a base insulating layer 115 on the substrate 110, a plurality of first conductive lines 120 on the base insulating layer 115, a plurality of channel structures 140 on the plurality of first conductive lines 120, a plurality of gate structures 150 including a plurality of gate electrodes 154 and a plurality of gate insulating films 152 provided between the plurality of channel structures 140 and the plurality of gate electrodes 154, an interlayer insulating layer 130 surrounding the plurality of channel structures 140 and the plurality of gate structures 150 on the plurality of first conductive lines 120, a plurality of second conductive lines 220 on the interlayer insulating layer 130, the plurality of channel structures 140, and the plurality of gate structures 150, the plurality of vertical conductive lines 240 penetrating the plurality of second conductive lines 220 and extending toward the substrate 110, and a plurality of ferroelectric patterns 230 provided between the plurality of second conductive lines 220 and the plurality of vertical conductive lines 240.

The substrate 110 may include silicon (Si), for example, crystalline Si, polycrystalline Si, or amorphous Si. Alternatively, the substrate 110 may include at least one compound semiconductor selected from among a semiconductor element such as germanium (Ge), silicon germanium (SiGe), silicon carbide (SiC), gallium arsenide (GaAs), indium arsenide (InAs), and indium phosphide (InP). Alternatively, the substrate 110 may include a silicon-on-insulator (SOI) substrate or a germanium-on-insulator (GeOI) substrate. For example, the substrate 110 may include a buried oxide (BOX) layer. The substrate 110 may include a conductive area, for example, a well-doped with impurities or a structure doped with impurities.

The base insulating layer 115 may be provided between the substrate 110 and the plurality of first conductive lines 120. The base insulating layer 115 may be provided between the plurality of first conductive lines 120. For example, the base insulating layer 115 may cover a lower surface and a side surface of each of the plurality of first conductive lines 120. In one or more example embodiments, upper surfaces of the base insulating layer 115 and the plurality of first conductive lines 120 may be located at the same vertical level forming a coplanar surface. The base insulating layer 115 may include silicon oxide, silicon nitride, silicon oxynitride, silicon carbide, silicon carbon nitride, an insulating material having permittivity lower than that of silicon oxide, or a combination thereof. For example, the base insulating layer 115 may include plasma enhanced oxide (PEOX), tetraethyl orthosilicate (TEOS), boro tetraethyl orthosilicate (BTEOS), phosphorus tetraethyl orthosilicate (PTEOS), boro phospho tetraethyl orthosilicate (BPTEOS), boro silicate glass (BSG), phospho silicate glass (PSG), boro phospho silicate glass (BPSG), etc. The lower permittivity material may include, for example, fluorine-doped silicon oxide, organosilicate glass, carbon-doped oxide, porous silicon oxide, porous organosilicate glass, spin-on organic polymeric dielectric, spin-on silicon based polymeric dielectric, or a combination thereof, but embodiments of the disclosure are not limited thereto.

The plurality of first conductive lines 120 may extend parallel to each other in the first horizontal direction (X direction). The plurality of first conductive lines 120 may be arranged with equal intervals in the second horizontal direction (Y direction). In one or more example embodiments, each of the plurality of first conductive lines 120 may include a conductive barrier film and a conductive charge layer covering the conductive barrier film. The conductive barrier film may include, for example, metal, conductive metal nitride, conductive metal silicide, or a combination thereof. For example, the conductive barrier film may include TiN. The conductive charge layer may include, for example, doped polysilicon, Ru, RuO, Pt, PtO, Ir, IrO, SRO(SrRuO), BSRO((Ba,Sr)RuO), CRO(CaRuO), BaRuO, La(Sr,Co)O, Ti, TiN, W, WN, Ta, TaN, TiAlN, TiSiN, TaAlN, TaSiN, or a combination thereof. The plurality of first conductive lines 120 may correspond to the plurality of bit lines BL shown in FIG. 1.

The plurality of channel structures 140 may be spaced apart from each other in each of the first horizontal direction (X direction) and the second horizontal direction (Y direction), on the plurality of first conductive lines 120. For example, the plurality of channel structures 140 may extend in the vertical direction (Z direction) while forming columns in each of the first horizontal direction (X direction) and the second horizontal direction (Y direction). Among the plurality of channel structures 140, the channel structures 140 arranged, forming columns, in the first horizontal direction (X direction), may be arranged on each of the plurality of first conductive lines 120. The channel structures 140 may include an oxide semiconductor material or a 2D semiconductor material. For example, the oxide semiconductor material may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O, or a combination thereof. For example, the 2D semiconductor material may include MoS₂, WSe₂, graphene, carbon nano tubes, or a combination thereof. For example, the channel structures 140 may include a single layer or multilayer including the oxide semiconductor material. In one or more example embodiments, the channel structures 140 may include a material having a bandgap energy greater than the bandgap energy of silicon. For example, the channel structure 140 may include a material having the bandgap energy of about 1.5 eV to about 5.6 eV. For example, the channel structures 140 may include a material that exhibits optimal channel performance when having the bandgap energy of about 2.0 eV to about 4.0 eV.

Each of the plurality of channel structures 140 may include a first impurity area 142, a channel region 144, and a second impurity area 146. In one or more example embodiments, the first impurity area 142, the channel region 144, and the second impurity area 146 included in each of the plurality of channel structures 140 may be sequentially arranged in the vertical direction (Z direction). The channel region 144 may be provided between the first impurity area 142 and the second impurity area 146. Each of the plurality of channel structures 140 is illustrated as having a circular horizontal cross-section, but embodiments of the disclosure are not limited thereto. For example, the horizontal cross-section of each of the plurality of channel structures 140 may have a shape of a square, a rectangle, a circle, an oval, or a polygon with five or more sides.

Each of the first impurity area 142, the channel region 144, and the second impurity area 146 may include the same oxide semiconductor material or 2D semiconductor material. The first impurity area 142 and the second impurity area 146 may be areas into which the same conductive impurities are injected. In one or more example embodiments, each of the first impurity area 142 and the second impurity area 146 may be an n-type area into which n-type impurities are injected, but embodiments of the disclosure are not limited thereto. For example, each of the first impurity area 142 and the second impurity area 146 may be a p-type area into which p-type impurities are injected. The channel region 144 may be an intrinsic semiconductor into which impurities are not injected, or an area into which different conductive impurities from the first impurity area 142 and the second impurity area 146 are injected. For example, when each of the first impurity area 142 and the second impurity area 146 is an n-type area into which n-type impurities are injected, the channel region 144 may be an intrinsic semiconductor into which impurities are not injected, or a p-type area into which p-type impurities are injected. For example, when each of the first impurity area 142 and the second impurity area 146 is a p-type area into which p-type impurities are injected, the channel region 144 may be an intrinsic semiconductor into which impurities are not injected, or an n-type area into which n-type impurities are injected.

The first impurity area 142 may be in contact with the first conductive line 120. At least a portion of the channel region 144 may be surrounded by the gate structure 150. In one or more example embodiments, the channel region 144 may be a portion of the channel structure 140 which is surrounded by the gate structure 150. In one or more example embodiments, the channel region 144 may include a portion of the channel structure 140 which is surrounded by the gate structure 150, and a portion adjacent thereto. In one or more example embodiments, the channel region 144 may be a part of the portion of the channel structure 140 which is surrounded by the gate structure 150. For example, the gate structure 150 may surround the channel region 144, a portion of the first impurity area 142 adjacent to the channel region 144, and a portion of the second impurity area 146 adjacent to the channel region 144. The gate insulating film 152 may be provided between the channel region 144 and the gate electrode 154. The second impurity area 146 may be in contact with each of the plurality of vertical conductive lines 240.

The plurality of gate structures 150 may surround at least a portion of the side surfaces of the plurality of channel structures 140. The plurality of gate electrodes 154 may extend in the second horizontal direction (Y direction) while being spaced apart from each other in the first horizontal direction (X direction). One gate electrode 154 may surround at least a portion of the side surfaces of the channel structures 140 forming columns in the second horizontal direction (Y direction) among the plurality of channel structures 140. The plurality of gate insulating films 152 may be provided between the plurality of channel structures 140 and the plurality of gate electrodes 154. In one or more example embodiments, the upper surface of the gate electrode 154 may be located at a lower vertical level than that of the upper surface of the channel structure 140, and the lower surface of the gate electrode 154 may be located at a higher vertical level than that of the lower surface of the channel structure 140. In one or more example embodiments, the upper surface of the gate insulating film 152 and the upper surface of the channel structure 140 may be located at the same vertical level, and the lower surface of the gate insulating film 152 and the lower surface of the channel structure 140 may be located at the same vertical level. The channel structure 140 and the gate structure 150 may configure the vertical channel transistor VCT shown in FIG. 1.

The gate insulating film 152 may include at least one selected from among silicon oxide, silicon nitride, silicon oxynitride, oxide/nitride/oxide (ONO), a high-k dielectric film having a higher dielectric constant than that of silicon oxide, and a ferroelectric material. For example, the gate insulating film 152 may have a dielectric constant of about 10 to about 25. In one or more example embodiments, the gate insulating film 152 may have a stack structure of a first dielectric film including silicon oxide and a second dielectric film including at least one selected from among a high-k dielectric material and a ferroelectric material. For example, the high-k dielectric material and the ferroelectric material may include at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanium (PZT), strontium bismuth tantalate (SBT), bismuth iron oxide (BFO), strontium titanium oxide (SrTiO), yttrium oxide (YO), aluminum oxide (AlO), or lead scandium tantalum oxide (PbScTaO).

The gate electrode 154 may include a doped semiconductor material, a metal material, a conductive metal nitride, or a combination thereof. For example, the gate electrode 154 may include doped polysilicon, Ti, TiN, Ta, TaN, W, WN, TiSiN, WSiN, or a combination thereof.

The interlayer insulating layer 130 may surround the plurality of channel structures 140 and the plurality of gate structures 150. The interlayer insulating layer 130 may include an insulating material having a lower permittivity than that of silicon oxide or silicon nitride. The plurality of channel structures 140 may penetrate the interlayer insulating layer 130. In one or more example embodiments, the upper surfaces of the plurality of channel structures 140 and the upper surface of the interlayer insulating layer 130 may be located at the same vertical level forming a coplanar surface. In one or more example embodiments, the lower surfaces of the plurality of channel structures 140 and the lower surface of the interlayer insulating layer 130 may be located at the same vertical level forming a coplanar surface. In one or more example embodiments, the interlayer insulating layer 130 may cover the upper surfaces and lower surfaces of the plurality of gate electrodes 154. For example, the upper surfaces of the plurality of channel structures 140, the upper surfaces of the plurality of gate insulating films 152, and the upper surface of the interlayer insulating layer 130 may be located at the same vertical level forming a coplanar surface. For example, the lower surfaces of the plurality of channel structures 140, the lower surfaces of the plurality of gate insulating films 152, and the lower surface of the interlayer insulating layer 130 may be located at the same vertical level forming a coplanar surface.

The plurality of second conductive lines 220 may extend in the second horizontal direction (Y direction) while being spaced apart from each other in each of the first horizontal direction (X direction) and the vertical direction (Z direction). A plurality of insulating layers 202 may be respectively provided between the plurality of second conductive lines 220 spaced apart from each other in the vertical direction (Z direction). In one or more example embodiments, the plurality of insulating layers 202 and the plurality of second conductive lines 220 may be alternately stacked in the vertical direction (Z direction). For example, each of the plurality of second conductive lines 220 may be provided between two insulating layers 202 adjacent to each other in the vertical direction (Z direction) among the plurality of insulating layers 202. For example, the insulating layer 202 at the top end among the plurality of insulating layers 202 may cover the upper surface of the second conductive line 220 at the top end among the plurality of second conductive lines 220, and the insulating layer 202 at the bottom end among the plurality of insulating layers 202 may cover the lower surface of the second conductive line 220 at the bottom end among the plurality of second conductive lines 220.

In one or more example embodiments, each of the plurality of second conductive lines 220 may include a conductive barrier film and a conductive charge layer covering the conductive barrier film. The conductive barrier film may include, for example, metal, conductive metal nitride, conductive metal silicide, or a combination thereof. For example, the conductive barrier film may include TiN. The conductive charge layer may include, for example, doped polysilicon, Ru, RuO, Pt, PtO, Ir, IrO, SRO(SrRuO), BSRO((Ba,Sr)RuO), CRO(CaRuO), BaRuO, La(Sr,Co)O, Ti, TiN, W, WN, Ta, TaN, TiAlN, TiSiN, TaAlN, TaSiN, or a combination thereof. Each of the plurality of insulating layers 202 may include silicon oxide, silicon nitride, silicon oxynitride, silicon carbide, silicon carbon nitride, an insulating material having a lower permittivity than that of silicon oxide, or a combination thereof.

A plurality of separating insulation layers 206 may be respectively provided between the plurality of second conductive lines 220 spaced apart from each other in the first horizontal direction (X direction). The plurality of separating insulation layers 206 may respectively fill a plurality of separation penetration trenches MDC that penetrate the plurality of insulating layers 202 and the plurality of second conductive lines 220 which are alternately arranged in the vertical direction (Z direction). The plurality of the separation penetration trenches MDC and the plurality of the separating insulation layer 206 filling the plurality of the separation penetration trenches MDC may each extend in the second horizontal direction (Y direction). Each of the plurality of separating insulation layers 206 may have a plate shape extending in the second horizontal direction (Y direction) and the vertical direction (Z direction). For example, the interlayer insulating layer 130 may be exposed to the bottom surface of the separation penetration trench MDC. The separating insulation layer 206 may include silicon oxide, silicon nitride, silicon oxynitride, silicon carbide, silicon carbon nitride, an insulating material having a lower permittivity than that of silicon oxide, or a combination thereof. In one or more example embodiments, the separating insulation layer 206 may include the same material as each of the plurality of insulating layers 202.

The vertical conductive line 240 may be arranged within a vertical through-hole MDH that penetrates the plurality of insulating layers 202 and the plurality of second conductive lines 220 which are alternately arranged in the vertical direction (Z direction). The horizontal width of the vertical conductive line 240 in the first horizontal direction (X direction) may be less than the horizontal width of the second conductive line 220 in the first horizontal direction (X direction). The ferroelectric pattern 230 may be provided between the vertical conductive line 240 and the insulating layers 202 and between the vertical conductive line 240 and the plurality of second conductive lines 220. The ferroelectric pattern 230 may surround the side surface of the vertical conductive line 240. The ferroelectric pattern 230 may surround the vertical conductive line 240 by continuously extending two-dimensionally. The second conductive lines 220 spaced apart from each other in the vertical direction (Z direction) may surround the side surface of the vertical conductive line 240 with the ferroelectric pattern 230 therebetween. The second conductive lines 220 spaced apart from each other in the vertical direction (Z direction) may surround the vertical conductive line 240 by continuously extending two-dimensionally with the ferroelectric pattern 230 therebetween.

In one or more example embodiments, the ferroelectric pattern 230 may cover all of the side surface of the vertical conductive line 240. Each of the plurality of vertical conductive lines 240 may include a conductive barrier film and a conductive charge layer covering the conductive barrier film. The conductive barrier film may include, for example, metal, conductive metal nitride, conductive metal silicide, or a combination thereof. For example, the conductive barrier film may include TiN. The conductive charge layer may include, for example, doped polysilicon, Ru, RuO, Pt, PtO, Ir, IrO, SRO(SrRuO), BSRO((Ba,Sr)RuO), CRO(CaRuO), BaRuO, La(Sr,Co)O, Ti, TiN, W, WN, Ta, TaN, TiAlN, TiSiN, TaAlN, TaSiN, or a combination thereof. The plurality of vertical conductive lines 240 may be the plurality of lower electrodes BE shown in FIG. 1.

The ferroelectric pattern 230 may include a ferroelectric material. For example, at least a portion of the ferroelectric pattern 230 may include a ferroelectric material. The ferroelectric pattern 230 may include at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanium (PZT), strontium bismuth tantalate (SBT), bismuth iron oxide (BFO), strontium titanium oxide (SrTiO), yttrium oxide (YO), aluminum oxide (AlO), and lead scandium tantalum oxide (PbScTaO). In one or more example embodiments, the ferroelectric pattern 230 may be doped with yttrium, magnesium, silicon, or barium.

The vertical conductive line 240 may have a plurality of electrode recesses 240R corresponding to the plurality of second conductive lines 220 spaced apart from each other in the vertical direction (Z direction). Each of the plurality of electrode recesses 240R may continuously extend two-dimensionally and may surround the vertical conductive line 240. Each of the plurality of electrode recesses 240R may have a concave shape extending into the vertical conductive line 240. The ferroelectric pattern 230 covering the surface of the vertical conductive line 240 in the plurality of electrode recesses 240R may define the plurality of dielectric recesses 230R corresponding to the plurality of electrode recesses 240R. For example, portions of the ferroelectric pattern 230 covering the surfaces of the vertical conductive line 240 in the plurality of electrode recesses 240R may define the plurality of dielectric recesses 230R. The second conductive line 220 may have a conductive protruding portion 220P that protrudes into the vertical through-hole MDH. The conductive protruding portion 220P may be a portion of the second conductive line 220 which fills the plurality of dielectric recesses 230R. The conductive protruding portion 220P and a portion of the ferroelectric pattern 230 defining the plurality of dielectric recesses 230R may fill the electrode recesses 240R. The conductive protruding portion 220P of the second conductive line 220 may have a convex shape extending into the vertical conductive line 240. The second conductive line 220, the ferroelectric pattern 230, and the vertical conductive line 240 may configure the ferroelectric capacitor CFE shown in FIG. 1. The plurality of second conductive lines 220 spaced apart from each other in the vertical direction (Z direction) may include the first power line PL1, the second power line PL2, and the third power line PL3, which are provided sequentially from the substrate 110 in the vertical direction (Z direction). For example, the first power line PL1, a portion of the ferroelectric pattern 230 provided between the first power line PL1 and the vertical conductive line 240, and the vertical conductive line 240, may configure the first ferroelectric capacitor CFE1 shown in FIG. 1, the second power line PL2, a portion of the ferroelectric pattern 230 provided between the second power line PL2 and the vertical conductive line 240, and the vertical conductive line 240 may configure the second ferroelectric capacitor CFE2 shown in FIG. 1, and the third power line PL3, a portion of the ferroelectric pattern 230 provided between the third power line PL3 and the vertical conductive line 240, and the vertical conductive line 240 may configure the third ferroelectric capacitor CFE3 shown in FIG. 1. The channel structure 140, the gate structure 150, the plurality of second conductive lines 220 spaced apart from each other in the vertical direction (Z direction), the ferroelectric pattern 230, and the vertical conductive line 240, may configure the memory cell MC shown in FIG. 1.

In the semiconductor memory device 1 according to one or more example embodiments, each of the plurality of vertical conductive lines 240 has the plurality of electrode recesses 240R, and the plurality of second conductive lines 220 has a plurality of conductive protruding portions 220P corresponding to the plurality of electrode recesses 240R, and, thus, the areas of the plurality of ferroelectric patterns 230 provided between the plurality of second conductive lines 220 and the plurality of vertical conductive lines 240 may increase. Accordingly, the capacitance of the plurality of ferroelectric capacitors CFE configured by the plurality of second conductive lines 220, the plurality of vertical conductive lines 240, and the plurality of ferroelectric patterns 230 may increase, and thus the semiconductor memory device 1 may have an increased degree of integration and improved reliability.

Furthermore, as the number of ferroelectric capacitors CFE may be increased by increasing the number of second conductive lines 220 spaced apart from each other in the vertical direction (Z direction), the bit numbers of information that may be stored in each of the plurality of memory cells MC included in the semiconductor memory device 1 may be easily increased.

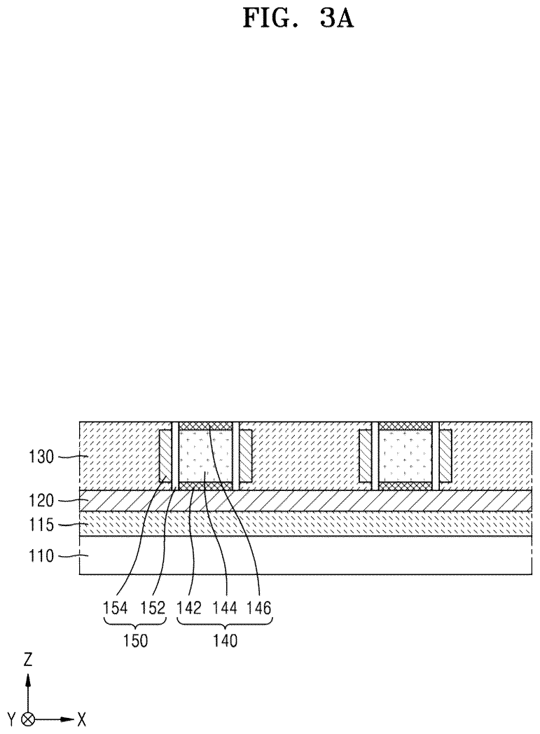

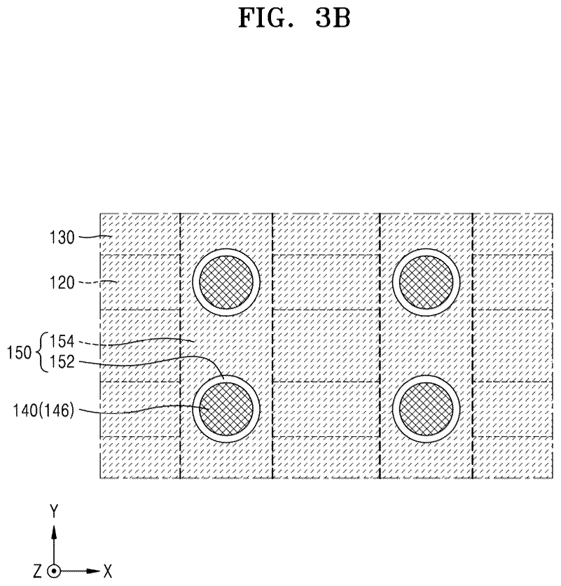

FIGS. 3A, 3B, 4A, 4B, 5A, 5B, 6A, 6B, 7A, 7B, 8A, 8B, 9A, 9B, 10A, 10B, 11A, 11B, 12A and 12B are diagrams showing a method of manufacturing a semiconductor memory device according to a process sequence, according to one or more example embodiments. In detail, FIGS. 3A, 4A, 5A, 6A, 7A, 8A, 9A, 10A, 11A, and 12A are vertical cross-sectional views cut along the position corresponding to FIG. 2A, and FIGS. 3B, 4B, 5B, 6B, 7B, 8B, 9B, 10B, 11B, and 12B are plan views viewed from above.

Referring to FIGS. 3A and 3B together, according to one or more example embodiments, the base insulating layer 115 and the plurality of first conductive lines 120 are formed on the substrate 110. The plurality of first conductive lines 120 may be spaced apart from each other in the second horizontal direction (Y direction), and may extend parallel to each other in the first horizontal direction (X direction). In one or more example embodiments, the plurality of first conductive lines 120 may be arranged in the second horizontal direction (Y direction) with equal intervals. The base insulating layer 115 may cover the substrate 110 and the side surface of the plurality of first conductive lines 120. For example, the base insulating layer 115 may be provided between the plurality of first conductive lines 120 and may cover the lower surface and the side surface of each of the plurality of first conductive lines 120. In one or more example embodiments, the lower portion of the base insulating layer 115, which covers the upper surface of the substrate 110 and the lower surfaces of the plurality of first conductive lines 120, is first formed, the plurality of first conductive lines 120 may be formed on the lower portion of the base insulating layer 115, and the lower portion of the base insulating layer 115 which covers the side surfaces of the plurality of first conductive lines 120, may be formed later. In one or more example embodiments, the base insulating layer 115 covering the upper surface of the substrate 110 may be formed, a plurality of trenches for removing portions of the base insulating layer 115 may be formed, and the plurality of first conductive lines 120 for filling the plurality of trenches may be formed. For example, the plurality of trenches may be formed by removing the portion of the base insulating layer 115 to extend parallel to each other in the first horizontal direction (X direction).

The plurality of channel structures 140 and the plurality of gate structures 150 may be formed on the plurality of first conductive lines 120. Each of the plurality of channel structures 140 may include the first impurity area 142, the channel region 144, and the second impurity area 146. The first impurity area 142 may be in contact with the first conductive line 120. Each of the plurality of channel structures 140 may have a shape of a circular horizontal cross-section, but embodiments of the disclosure are not limited thereto. For example, the horizontal cross-section of each of the plurality of channel structures 140 may have a shape of a square, a rectangle, a circle, an oval, or a polygon larger than a quadrilateral.

In one or more example embodiments, the first impurity area 142, the channel region 144, and the second impurity area 146 may be injected with impurities, or may not be injected with impurities, in a formation process. In one or more example embodiments, after forming the channel structure 140 not to be injected with impurities or to have a certain impurity concentration, the first impurity area 142 and the second impurity area 146, which are distinguished from the channel region 144, may be formed by injecting impurities into portions of the channel structure 140. Each of the first impurity area 142, the channel region 144, and the second impurity area 146 may include the same oxide semiconductor material or 2D semiconductor material. The channel region 144 may include an intrinsic semiconductor into which impurities are not injected, or may be formed by injecting different conductive impurities from that of the first impurity area 142 and the second impurity area 146. In one or more example embodiments, each of the first impurity area 142 and the second impurity area 146 may be formed by injecting n-type impurities, but embodiments of the disclosure are not limited thereto. For example, each of the first impurity area 142 and the second impurity area 146 may be formed by injecting p-type impurities.

The plurality of gate structures 150 may include the plurality of gate electrodes 154 and the plurality of gate insulating films 152 provided between the plurality of channel structures 140 and the plurality of gate electrodes 154. The plurality of gate structures 150 may be formed to surround at least a portion of the side surfaces of the plurality of channel structures 140. The plurality of gate electrodes 154 may be spaced apart from each other in the first horizontal direction (X direction) and may extend in the second horizontal direction (Y direction). Each of the plurality of gate electrodes 154 may be formed to surround at least a portion of the side surfaces of the channel structures 140 forming columns in the second horizontal direction (Y direction) among the plurality of channel structures 140. The plurality of gate insulating films 152 may be formed to surround the side surfaces of the plurality of channel structures 140 to be provided between the plurality of channel structures 140 and the plurality of gate electrodes 154. The horizontal cross-section of each of the plurality of gate insulating films 152 may have a shape of a square, a rectangle, a circle, an oval, or a polygon larger than a quadrilateral corresponding to the horizontal cross-section of each of the plurality of channel structures 140.

The interlayer insulating layer 130 may be formed to surround the plurality of channel structures 140 and the plurality of gate structures 150. In one or more example embodiments, the interlayer insulating layer 130 may be formed such that the upper surfaces of the plurality of channel structures 140 and the upper surface of the interlayer insulating layer 130 are located at the same vertical level forming a coplanar surface, and the lower surfaces of the plurality of channel structures 140 and the lower surface of the interlayer insulating layer 130 are located at the same vertical level forming a coplanar surface. In one or more example embodiments, the interlayer insulating layer 130 may be formed to cover the upper surfaces and lower surfaces of the plurality of gate electrodes 154.

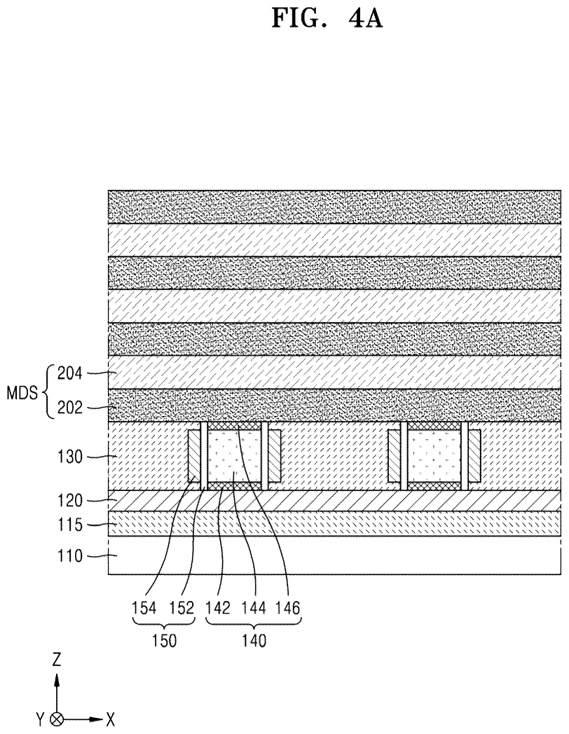

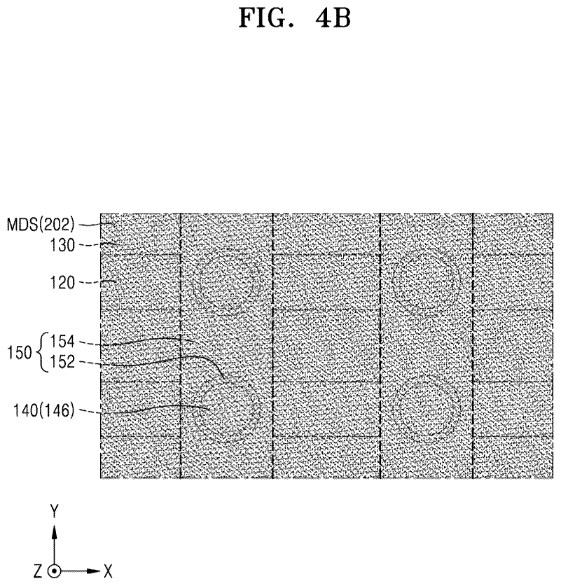

Referring to FIGS. 4A and 4B together, according to one or more example embodiments, the plurality of insulating layers 202 and a plurality of sacrificial layers 204 may be formed on the interlayer insulating layer 130, the plurality of channel structures 140, and the plurality of gate structures 150. The plurality of insulating layers 202 and the plurality of sacrificial layers 204 may be alternately stacked on the interlayer insulating layer 130, the plurality of channel structures 140, and the plurality of gate structures 150. The plurality of insulating layers 202 and the plurality of sacrificial layers 204 may be referred to as a mold structure MDS. Each of the plurality of sacrificial layers 204 may be provided between two insulating layers 202 adjacent to each other in the vertical direction (Z direction) among the plurality of insulating layers 202. In one or more example embodiments, the insulating layer 202 at the top end among the plurality of insulating layers 202 may be formed to cover an upper surface of the sacrificial layer 204 at the top end among the plurality of sacrificial layers 204, and the insulating layer 202 at the bottom end among the plurality of insulating layers 202 may be formed to cover a lower surface of the sacrificial layer 204 at the bottom end among the plurality of sacrificial layers 204. FIGS. 4A and 4B illustrate that the mold structure MDS includes four insulating layers 202 and three sacrificial layers 204, but embodiments of the disclosure are not limited thereto. For example, the mold structure MDS may include five or more insulating layers 202 and four or more sacrificial layers 204.

The plurality of insulating layers 202 and the plurality of sacrificial layers 204 may include materials having an etching selectivity with respect to each other. In one or more example embodiments, the plurality of insulating layers 202 may include silicon oxide, and the plurality of sacrificial layers 204 may include a carbon-containing material such as silicon nitride or silicon carbide.

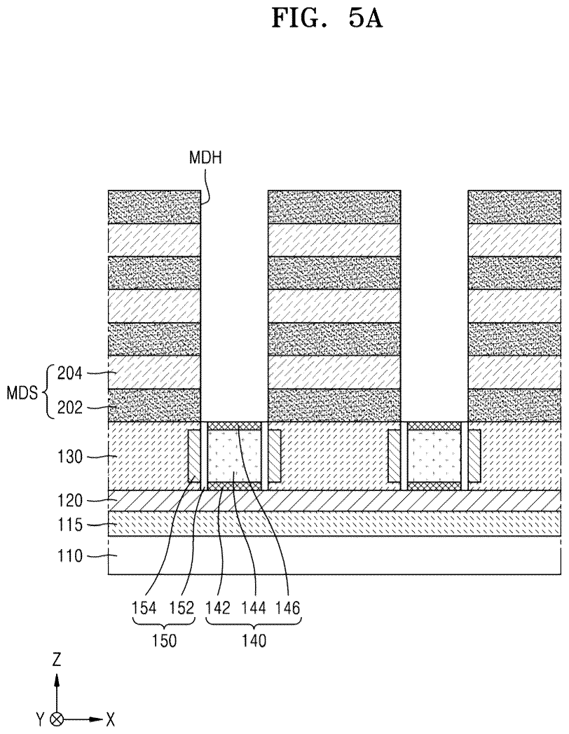

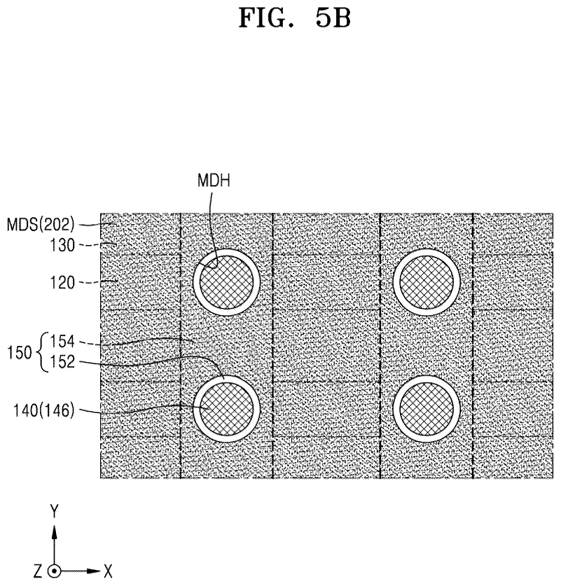

Referring to FIGS. 5A and 5B together, according to one or more example embodiments, a plurality of vertical through-holes MDH may be formed by removing portions of the mold structure MDS. The plurality of vertical through-holes MDH may be formed to penetrate the mold structure MDS from an upper surface to a lower surface thereof. For example, the plurality of vertical through-holes MDH may be formed to penetrate both the plurality of insulating layers 202 and the plurality of sacrificial layers 204 included in the mold structure MDS. In one or more example embodiments, the vertical through-hole MDH may be formed to overlap the plurality of channel structures 140 in the vertical direction (Z direction). For example, the plurality of channel structures 140 may be exposed from the bottom surface of each of the plurality of vertical through-holes MDH. In one or more example embodiments, the vertical through-hole MDH may be formed to overlap the plurality of channel structures 140 and the plurality of gate insulating films 152 in the vertical direction (Z direction). For example, the plurality of channel structures 140 and the plurality of gate insulating films 152 may be exposed through the bottom surfaces of the plurality of vertical through-holes MDH.

The plurality of vertical through-holes MDH may be arranged in columns and rows along the first horizontal direction (X direction) and the second horizontal direction (Y direction). For example, the plurality of vertical through-holes MDH may be spaced apart from each other along the plurality of second conductive lines 220 extending in the first horizontal direction (X direction). The horizontal width of the vertical through-hole MDH may be substantially the same as the horizontal width of the channel structure 140 or the total horizontal width of the gate insulating film 152 surrounding the channel structure 140 and the channel structure 140. For example, the plurality of vertical through-holes MDH may have a shape of a square, a rectangle, a circle, an oval, or a polygon larger than a quadrilateral.

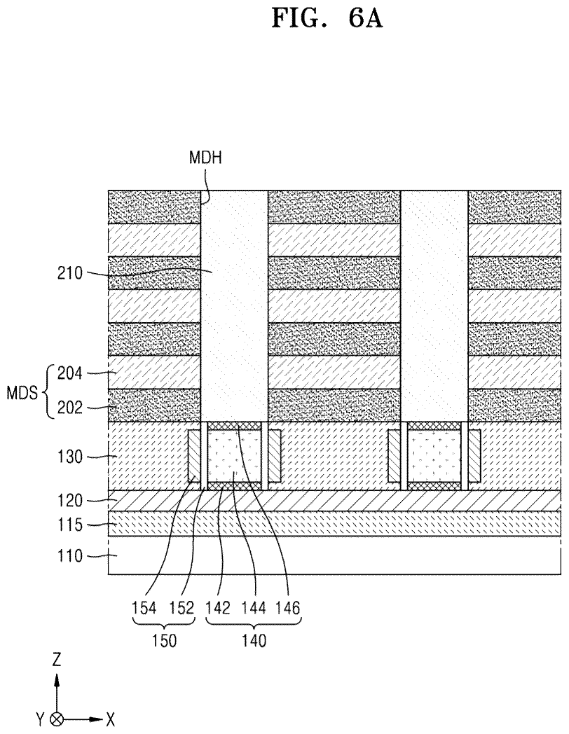

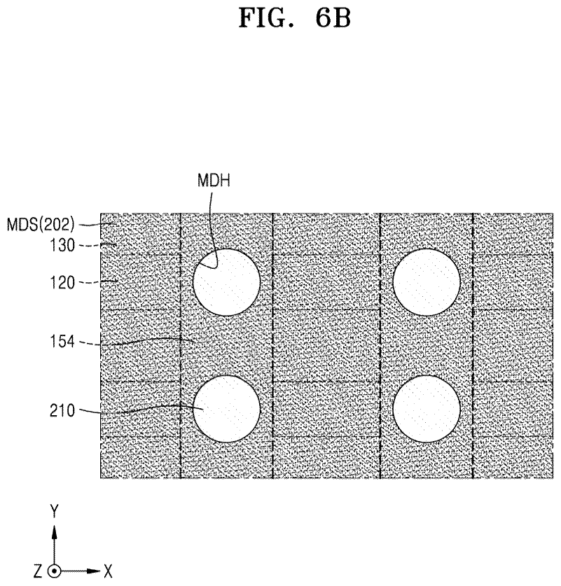

Referring to FIGS. 6A and 6B together, according to one or more example embodiments, a plurality of charge sacrificial layers 210 filling the plurality of vertical through-holes MDH may be formed. Each of the plurality of charge sacrificial layers 210 may include a material having an etching selectivity with respect to each of the plurality of insulating layers 202 and the plurality of sacrificial layers 204. Each of the plurality of charge sacrificial layers 210 may include a material having an etching selectivity with respect to each of the plurality of insulating layers 202 and the plurality of sacrificial layers 204 among an insulating material including silicon, such as silicon oxide or silicon oxynitride, a carbon-containing material, such as an amorphous carbon layer (ACL) or a spin-on hardmask (SOH), or a combination thereof. For example, each of the plurality of insulating layers 202 may include silicon oxide, each of the plurality of sacrificial layers 204 may include silicon nitride, and each of the plurality of charge sacrificial layers 210 may include a carbon-containing material.

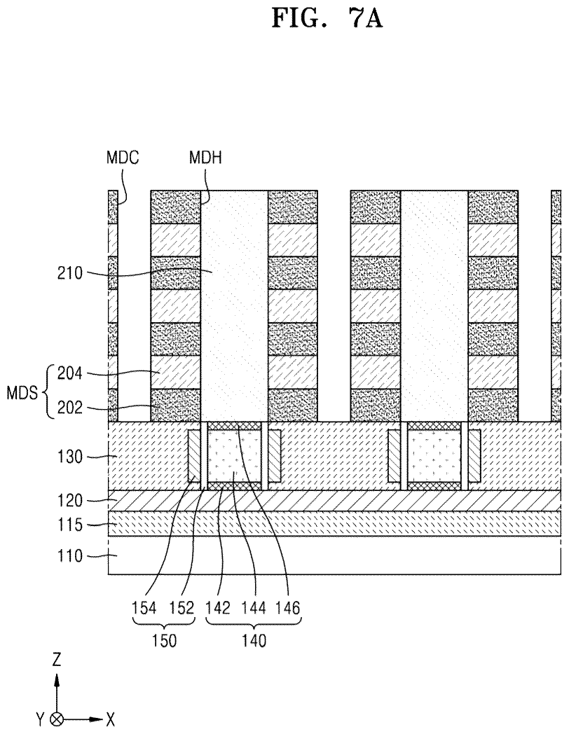

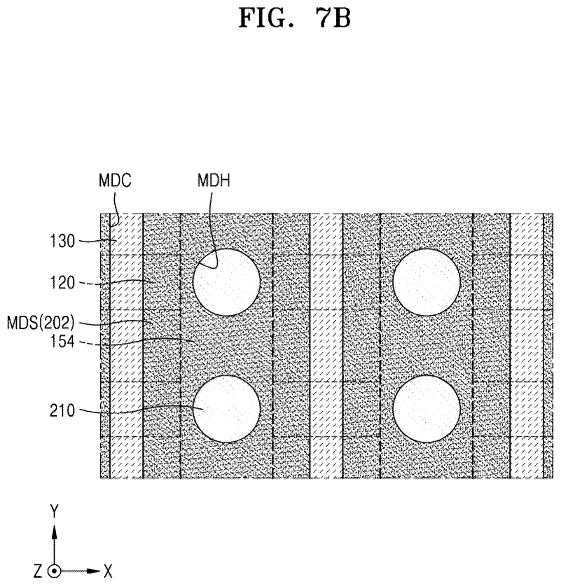

Referring to FIGS. 7A and 7B together, according to one or more example embodiments, the separation penetration trench MDC that penetrates portions of the mold structure MDS may be formed. Each of the plurality of separation penetration trenches MDC may extend in the second horizontal direction (Y direction). The plurality of separation penetration trenches MDC may be formed not to overlap the plurality of channel structures 140 and the plurality of gate structures 150 in the vertical direction (Z direction). For example, each of the plurality of separation penetration trenches MDC may extend two-dimensionally in the second horizontal direction (Y direction) between two gate electrodes 154 adjacent to each other in the first horizontal direction (X direction). The separation penetration trench MDC may be formed to penetrate the mold structure MDS from an upper surface to a lower surface thereof. For example, the plurality of separation penetration trenches MDC may be formed to penetrate all of the plurality of insulating layers 202 and the plurality of sacrificial layers 204 included in the mold structure MDS. For example, the interlayer insulating layer 130 may be exposed through the bottom surface of each of the plurality of separation penetration trenches MDC.

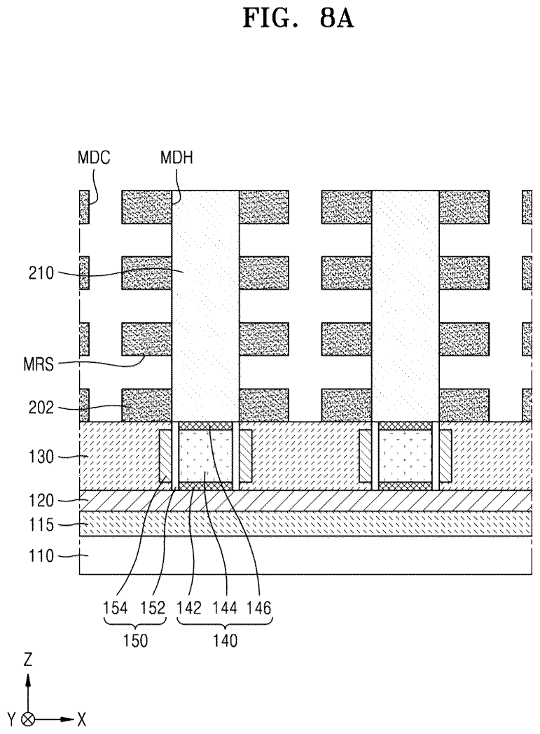

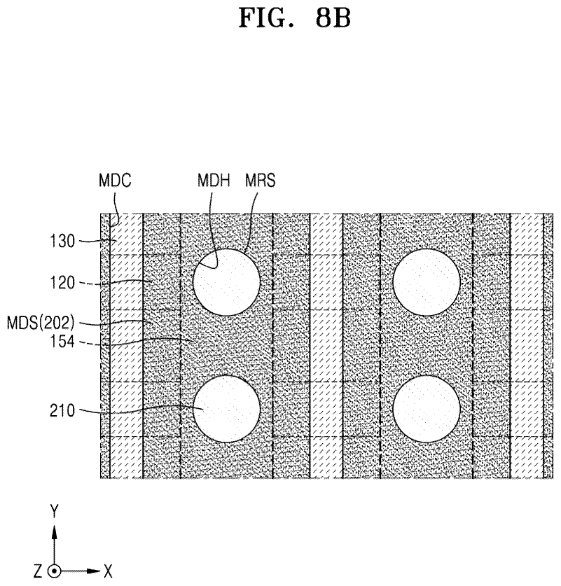

Referring to FIGS. 7A and 7B and FIGS. 8A and 8B together, according to one or more example embodiments, the plurality of sacrificial layers 204 may be removed through the plurality of separation penetration trenches MDC. Spaces from which the plurality of sacrificial layers 204 are removed may be referred to as a plurality of removed spaces MRS. The plurality of removed spaces MRS may surround the plurality of charge sacrificial layers 210. For example, portions of the side surfaces of the plurality of charge sacrificial layers 210 may be exposed through the inner walls of the plurality of removed spaces MRS.

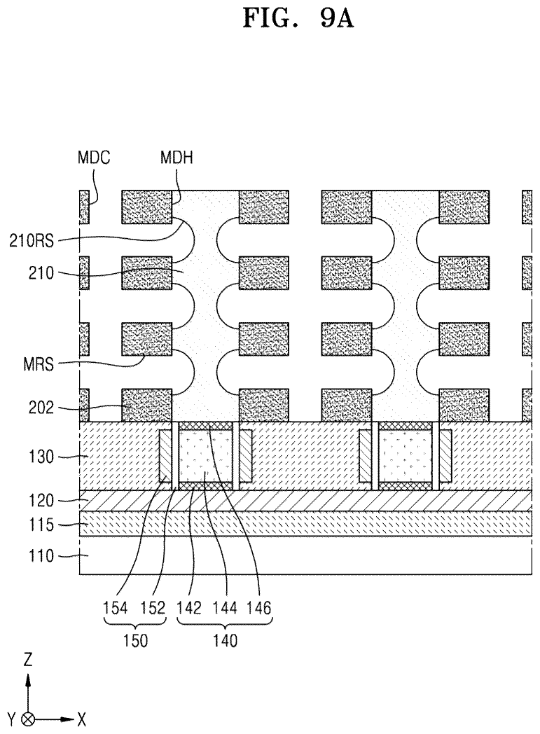

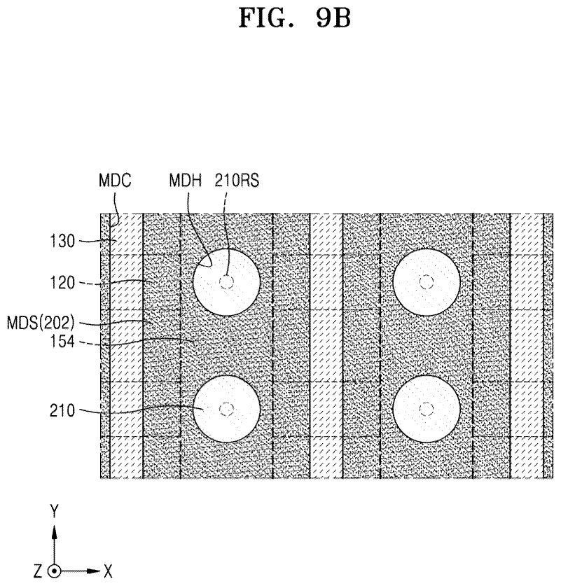

Referring to FIGS. 9A and 9B together, according to one or more example embodiments, a plurality of recess spaces 210RS may be formed by removing portions of the plurality of charge sacrificial layers 210 through the plurality of removed spaces MRS. Each of the plurality of recess spaces 210RS may surround the charge sacrificial layer 210 by continuously extending two-dimensionally. Each of the plurality of recess spaces 210RS may have a concave shape extending into the charge sacrificial layer 210.

In one or more example embodiments, the plurality of recess spaces 210RS may be formed by removing portions of the plurality of charge sacrificial layers 210 exposed through the plurality of removed spaces MRS through isotropic etching. For example, the maximum height of each of the plurality of recess spaces 210RS may be greater than the height of each of the plurality of removed spaces MRS in the vertical direction (Z direction).

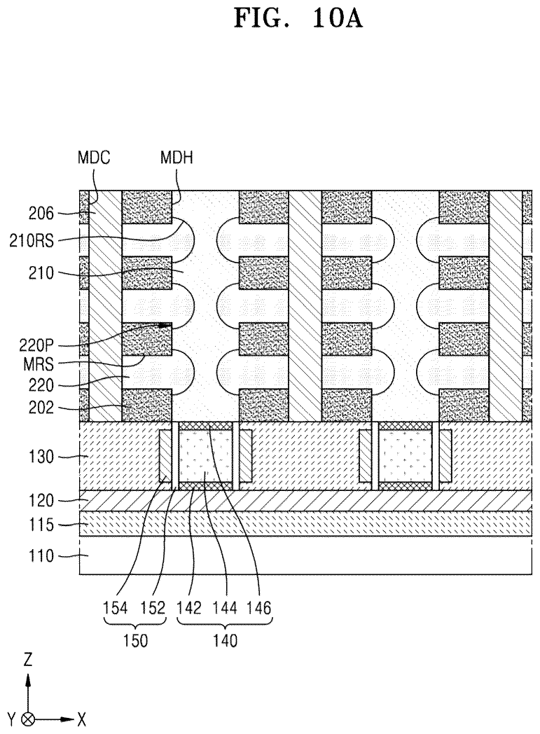

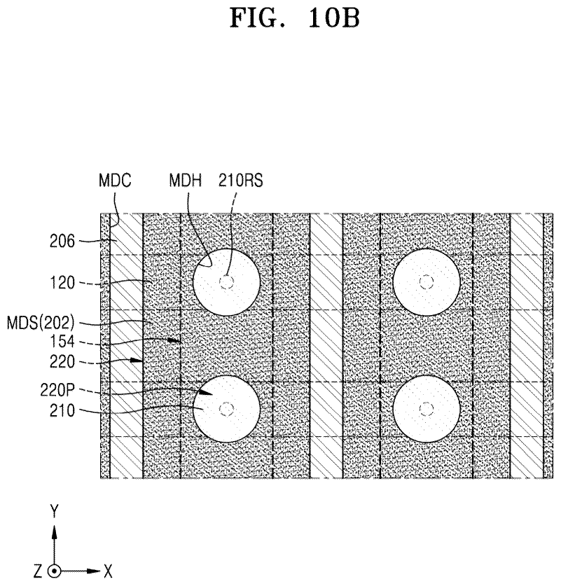

Referring to FIGS. 10A and 10B together, according to one or more example embodiments, the plurality of second conductive lines 220 that fill the plurality of removed spaces MRS and the plurality of recess spaces 210RS and the plurality of separating insulation layers 206 that fill the plurality of separation penetration trenches MDC may be formed.

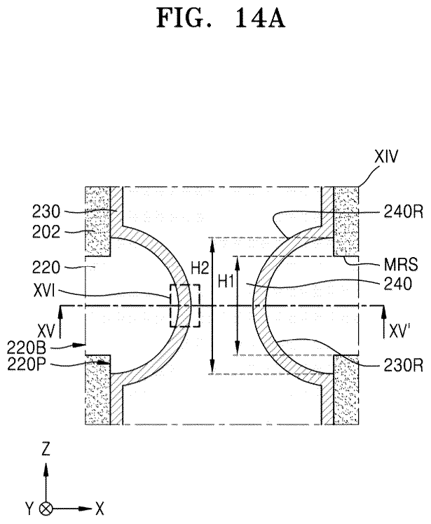

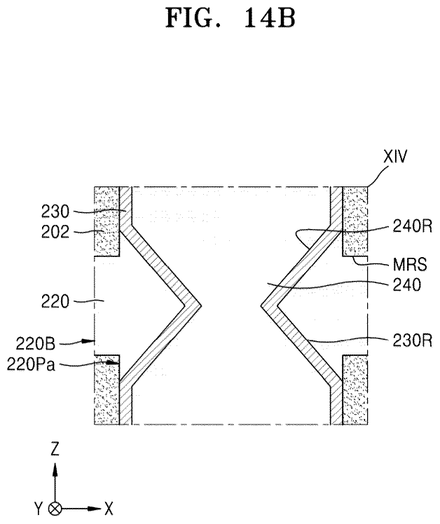

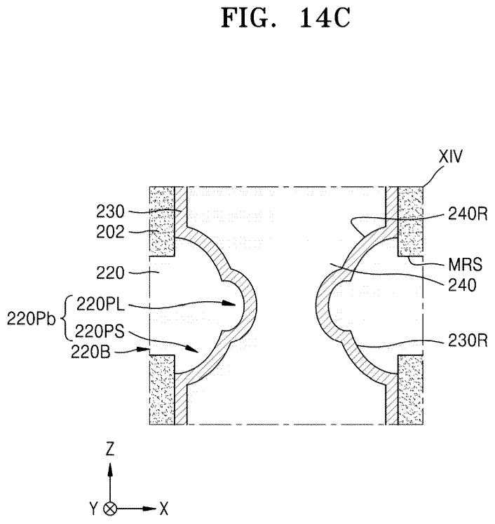

The plurality of second conductive lines 220 may be spaced apart from each other in each of the first horizontal direction (X direction) and the vertical direction (Z direction) and may extend in the second horizontal direction (Y direction). The plurality of second conductive lines 220 spaced apart from each other in the vertical direction (Z direction) may include the first power line PL1, the second power line PL2, and the third power line PL3 which are sequentially arranged from the substrate 110 in the vertical direction (Z direction). The plurality of insulating layers 202 may be provided between the plurality of second conductive lines 220 spaced apart from each other in the vertical direction (Z direction). In one or more example embodiments, the plurality of insulating layers 202 and the plurality of second conductive lines 220 may be alternately arranged in the vertical direction (Z direction). For example, each of the plurality of second conductive lines 220 may be provided between two insulating layers 202 adjacent to each other in the vertical direction (Z direction) among the plurality of insulating layers 202. Each of the plurality of second conductive lines 220 may include a conductive base portion (220B in FIG. 14A) that fills the removed space MRS and the conductive protruding portion 220P that fills the recess space 210RS. For example, the plurality of vertical through-holes MDH may be filled with the plurality of charge sacrificial layers 210 and the plurality of conductive protruding portions 220P. The conductive protruding portion 220P of the second conductive line 220 may have a convex shape extending into the vertical conductive line 240. The conductive protruding portion 220P of the second conductive line 220 may continuously extend two-dimensionally and may surround the charge sacrificial layer 210. As the maximum height of each of the plurality of recess spaces 210RS may be greater than the height of the plurality of removed spaces MRS in the vertical direction (Z direction), the maximum height of the conductive protruding portion 220P may be greater than the height of the conductive base portion 220B in the vertical direction (Z direction).

The plurality of separating insulation layers 206 may be formed to fill the plurality of separation penetration trenches MDC. The separating insulation layer 206 may be provided between the plurality of second conductive lines 220 spaced apart from each other in the first horizontal direction (X direction). Each of the plurality of separating insulation layers 206 may extend in the second horizontal direction (Y direction). Each of the plurality of separating insulation layers 206 may have a plate shape extending in the second horizontal direction (Y direction) and the vertical direction (Z direction). In one or more example embodiments, the separating insulation layer 206 may include the same material as that of each of the plurality of insulating layers 202.

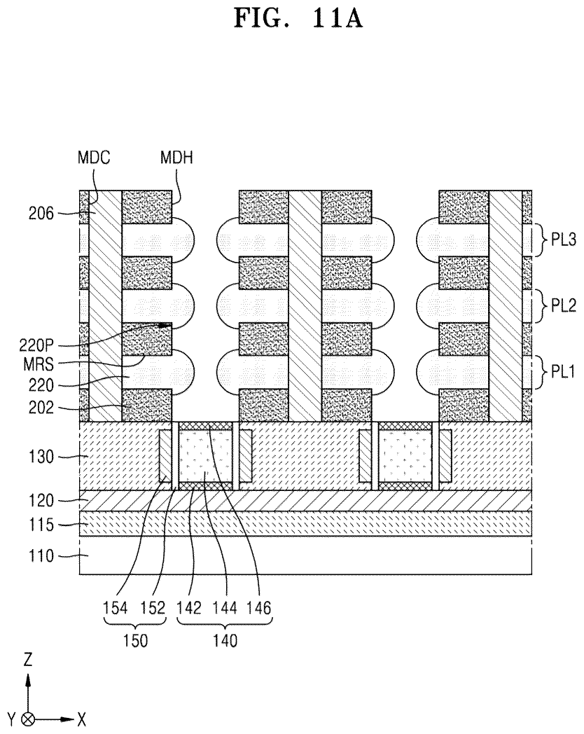

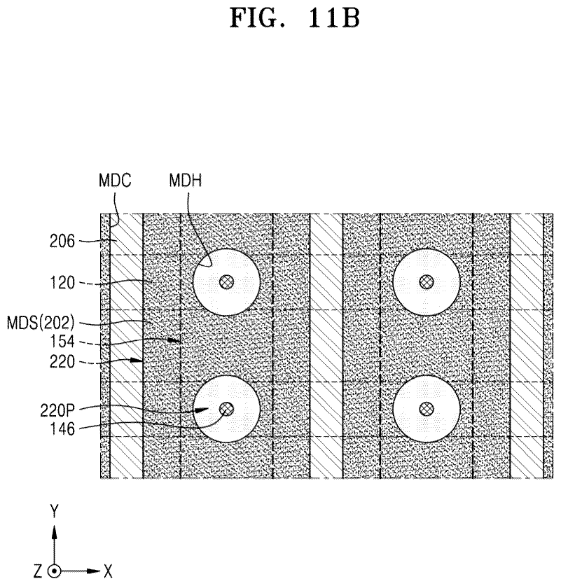

Referring to FIGS. 10A and 10B and FIGS. 11A and 11B together, according to one or more example embodiments, by removing the plurality of charge sacrificial layers 210, the plurality of conductive protruding portions 220P and the plurality of channel structures 140 may be exposed with the plurality of vertical through-holes MDH. For example, the second impurity area 146 of each of the plurality of channel structures 140 may be exposed through the bottom surface of each of the plurality of vertical through-holes MDH.

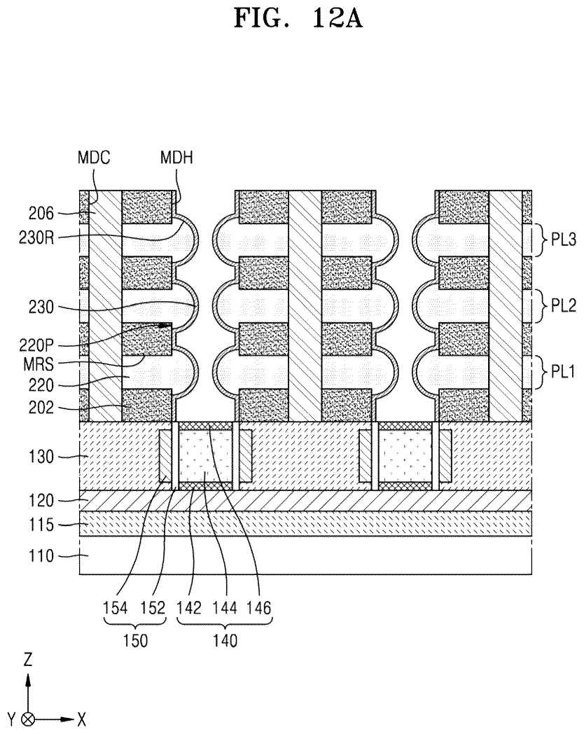

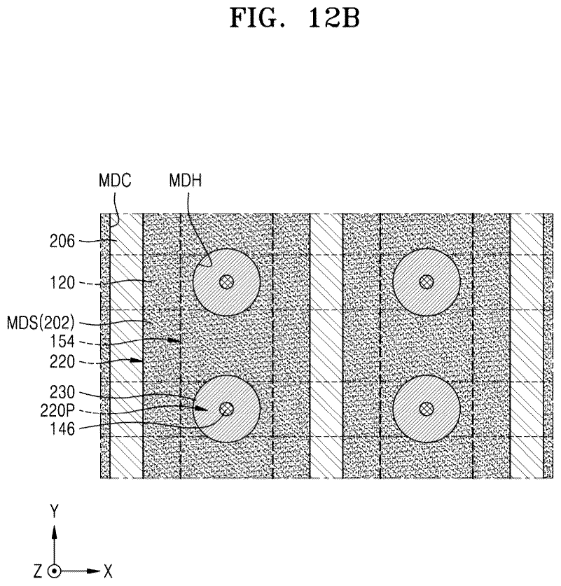

Referring to FIGS. 12A and 12B together, according to one or more example embodiments, the plurality of ferroelectric patterns 230 that cover the surfaces of the plurality of conductive protruding portions 220P may be formed within the plurality of vertical through-holes MDH. The plurality of ferroelectric patterns 230 may be formed by forming a ferroelectric material layer that covers the surface of each of the plurality of conductive protruding portions 220P, the plurality of insulating layers 202, and the plurality of second impurity areas 146, which are exposed within the plurality of vertical through-holes MDH, and then, removing a portion of the ferroelectric material layer covering the bottom surfaces of the plurality of vertical through-holes MDH. The plurality of ferroelectric patterns 230 may be formed to cover the side surfaces of the plurality of insulating layers 202 and the surfaces of the plurality of conductive protruding portions 220P, which are exposed within the plurality of vertical through-holes MDH. Each of the plurality of ferroelectric patterns 230 may be formed not to cover the second impurity area 146 of each of the plurality of channel structures 140. For example, after the plurality of ferroelectric patterns 230 are formed, the second impurity area 146 of each of the plurality of channel structures 140 may be exposed through the bottom surface of each of the plurality of vertical through-holes MDH.

By forming the plurality of vertical conductive lines 240 shown in FIGS. 2A and 2B, the semiconductor memory device 1 may be formed. The plurality of vertical conductive lines 240 may be formed to fill the plurality of vertical through-holes MDH. The plurality of vertical conductive lines 240 may be formed to cover the plurality of ferroelectric patterns 230 and the plurality of second impurity areas 146. For example, the side surfaces of the plurality of vertical conductive lines 240 may be in contact with the side surfaces of the plurality of ferroelectric patterns 230, and the lower surfaces of the plurality of vertical conductive lines 240 may be in contact with the upper surfaces of the plurality of second impurity areas 146.

The plurality of vertical conductive lines 240 may be formed to have the plurality of electrode recesses 240R corresponding to the plurality of second conductive lines 220 spaced apart from each other in the vertical direction (Z direction) with the plurality of ferroelectric patterns 230 therebetween. Each of the plurality of electrode recesses 240R may continuously extend two-dimensionally and may surround the vertical conductive line 240. Each of the plurality of electrode recesses 240R may have a concave shape extending into the vertical conductive line 240. The ferroelectric pattern 230 covering the surface of the vertical conductive line 240 in the plurality of electrode recesses 240R may define the plurality of dielectric recesses 230R corresponding to the plurality of electrode recesses 240R. The conductive protruding portion 220P may be a portion of the second conductive line 220 that fills each of the plurality of dielectric recesses 230R. The plurality of dielectric recesses 230R may be substantially the same as the recess space 210RS shown in FIGS. 9A, 9B, 10A and 10B.

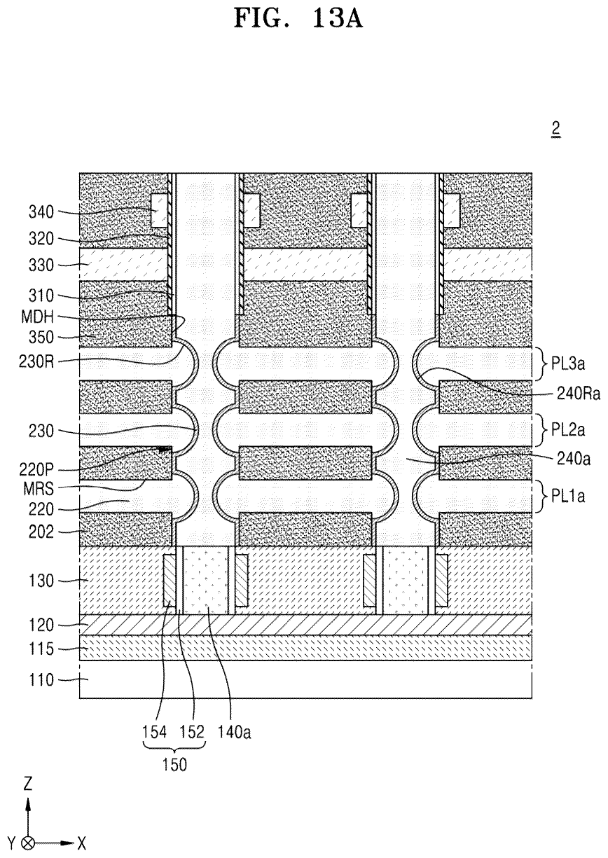

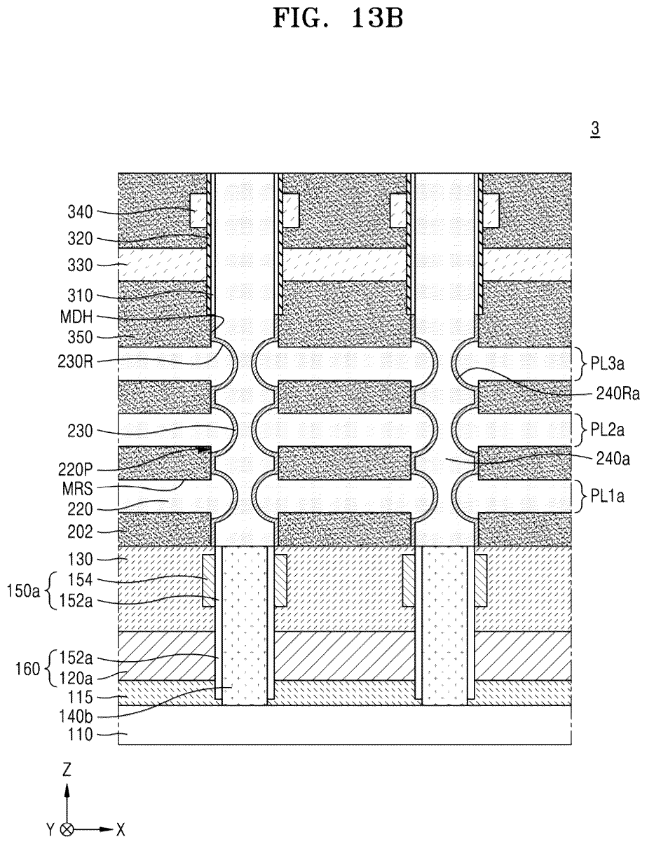

FIGS. 13A and 13B are diagrams respectively showing semiconductor memory devices 2 and 3 according to one or more example embodiments. In detail, FIG. 13A is a vertical cross-sectional view cut in the first horizontal direction (X direction) along vertical conductive lines 240a of the semiconductor memory device 2, and FIG. 13B is a vertical cross-sectional view cut in the first horizontal direction (X direction) along the vertical conductive lines 240a of the semiconductor memory device 3. Among the descriptions presented with reference to FIGS. 13A and 13B, redundant descriptions to those presented with reference to FIGS. 2A and 2B may be omitted.

Referring to FIG. 13A, according to one or more example embodiments, the semiconductor memory device 2 may include the substrate 110, the base insulating layer 115 on the substrate 110, the plurality of first conductive lines 120 on the base insulating layer 115, a plurality of channel structures 140a on the plurality of first conductive lines 120, the plurality of gate structures 150 including the plurality of gate electrodes 154 and the plurality of gate insulating films 152 provided between the plurality of channel structures 140a and the plurality of gate electrodes 154, the interlayer insulating layer 130 on the plurality of first conductive lines 120, surrounding the plurality of channel structures 140a and the plurality of gate structures 150, the plurality of second conductive lines 220 on the interlayer insulating layer 130, the plurality of channel structures 140a, and the plurality of gate structures 150, a plurality of third conductive lines 330 on the plurality of second conductive lines 220, a plurality of fourth conductive lines 340 on the plurality of third conductive lines 330, a plurality of vertical conductive lines 240a penetrating the plurality of fourth conductive lines 340, the plurality of third conductive lines 330, and the plurality of second conductive lines 220 and extending toward the substrate 110, the plurality of ferroelectric patterns 230 provided between the plurality of second conductive lines 220 and the plurality of vertical conductive lines 240a, and an interconnect insulating layer 350 surrounding the plurality of third conductive lines 330, the plurality of fourth conductive lines 340, and the upper portions of the plurality of vertical conductive lines 240a. As the channel structure 140a and the vertical conductive line 240a are respectively and substantially similar to the channel structure 140 and the vertical conductive line 240 shown in FIGS. 2A and 2B, redundant descriptions thereof may be omitted.

The plurality of second conductive lines 220 may have a plate shape and extend in the first horizontal direction (X direction) and the second horizontal direction (Y direction). The plurality of second conductive lines 220 may include a first power line PL1a, a second power line PL2a, and a third power line PL3a, which are sequentially arranged in the vertical direction (Z direction). The plurality of second conductive lines 220, the plurality of vertical conductive lines 240a, and portions of the ferroelectric pattern 230 provided between the plurality of second conductive lines 220 and the plurality of vertical conductive lines 240a, may configure a plurality of ferroelectric capacitors.

The plurality of third conductive lines 330 may extend in the first horizontal direction (X direction) while being spaced apart from each other in the second horizontal direction (Y direction). The plurality of fourth conductive lines 340 may extend in the second horizontal direction (Y direction) while being spaced apart from each other in the first horizontal direction (X direction). The plurality of third conductive lines 330 and the plurality of fourth conductive lines 340 may each include a conductive barrier film and a conductive charge layer covering the conductive barrier film. A plurality of upper gate insulating films 310 and a plurality of upper channel films 320 may be provided between the plurality of vertical conductive lines 240a and the plurality of third conductive lines 330 and between the plurality of vertical conductive lines 240a and the plurality of fourth conductive lines 340. For example, the plurality of upper gate insulating films 310 may cover the side surfaces of the upper portions of the plurality of vertical conductive lines 240a. Each of the plurality of upper gate insulating films 310 may include at least one selected from among silicon oxide, silicon nitride, silicon oxynitride, oxide/nitride/oxide (ONO), a high-k dielectric film having a higher dielectric constant than that of silicon oxide, and a ferroelectric material. The plurality of upper channel films 320 may cover the plurality of upper gate insulating films 310. The plurality of upper channel films 320 may include a semiconductor element, such as Si or Ge, at least one compound semiconductor selected from among SiGe, SiC, GaAs, InAs, and InP, an oxide semiconductor material, or a 2D semiconductor material.

The upper gate insulating film 310, the upper channel film 320, the third conductive line 330, the upper portion of the vertical conductive line 240a, and the fourth conductive line 340 may configure a read transistor. The third conductive line 330, the upper portion of the vertical conductive line 240a, and the fourth conductive line 340 may be respectively a drain, a gate, and a source of the read transistor. The channel structure 140a and the gate structure 150 may configure a write transistor. The semiconductor memory device 2 may be 2 Transistor n Capacitor ferroelectric random access memory (2TnC FeRAM) including a plurality of memory cells consisting of the write transistor, the read transistor, and each of the plurality of ferroelectric capacitors.

Referring to FIG. 13B, according to one or more example embodiments, the semiconductor memory device 3 may include the substrate 110, the base insulating layer 115 on the substrate 110, a plurality of first conductive lines 120a on the base insulating layer 115, the plurality of gate electrodes 154 on the plurality of first conductive lines 120a, a plurality of channel structures 140b penetrating the plurality of first conductive lines 120a and the plurality of gate electrodes 154, a plurality of gate insulating films 152a provided between the plurality of channel structures 140b and the plurality of first conductive lines 120a and between the plurality of channel structures 140b and the plurality of gate electrodes 154, the plurality of channel structures 140b on the plurality of first conductive lines 120a, the interlayer insulating layer 130 surrounding the plurality of gate insulating films 152a and the plurality of gate electrodes 154, the plurality of second conductive lines 220 on the interlayer insulating layer 130, the plurality of channel structures 140b, the plurality of gate insulating films 152a, and the plurality of gate electrodes 154, the plurality of third conductive lines 330 on the plurality of second conductive lines 220, the plurality of fourth conductive lines 340 on the plurality of third conductive lines 330, the plurality of vertical conductive lines 240a penetrating the plurality of fourth conductive lines 340, the plurality of third conductive lines 330, and the plurality of second conductive lines 220 and extending toward the substrate 110, the plurality of ferroelectric patterns 230 provided between the plurality of second conductive lines 220 and the plurality of vertical conductive lines 240a, and the interconnect insulating layer 350 surrounding the plurality of third conductive lines 330, the plurality of fourth conductive lines 340, and the upper portions of the plurality of vertical conductive lines 240a. As the first conductive line 120a, the gate insulating film 152a, and the channel structure 140b are respectively and substantially similar to the first conductive line 120, the gate insulating film 152, and the channel structure 140 shown in FIGS. 2A and 2B, redundant descriptions thereof may be omitted.

The plurality of gate electrodes 154, and portions of the plurality of gate insulating films 152a provided between the plurality of gate electrodes 154 and the plurality of channel structures 140b, may configure a plurality of gate structures 150a, and the plurality of first conductive lines 120a, and portions of the plurality of gate insulating films 152a provided between the plurality of first conductive lines 120a and the plurality of channel structures 140b, may configure a plurality of lower gate structures 160.

The plurality of first conductive lines 120a may extend in the first horizontal direction (X direction) parallel to each other. The plurality of first conductive lines 120a may be arranged with equal intervals in the second horizontal direction (Y direction).

The plurality of second conductive lines 220 may have a plate shape and extend in the first horizontal direction (X direction) and the second horizontal direction (Y direction). The plurality of second conductive lines 220 may include the first power line PL1a, the second power line PL2a, and the third power line PL3a, which are sequentially arranged in the vertical direction (Z direction). The plurality of second conductive lines 220, the plurality of vertical conductive lines 240a, and portions of the ferroelectric pattern 230 provided between the plurality of second conductive lines 220 and the plurality of vertical conductive lines 240a, may configure a plurality of ferroelectric capacitors.

The plurality of third conductive lines 330 may extend in the first horizontal direction (X direction) while being spaced apart from each other in the second horizontal direction (Y direction). The plurality of fourth conductive lines 340 may extend in the second horizontal direction (Y direction) while being spaced apart from each other in the first horizontal direction (X direction). Each of the plurality of third conductive lines 330 and the plurality of fourth conductive lines 340 may include a conductive barrier film and a conductive charge layer covering the conductive barrier film. The plurality of upper gate insulating films 310 and the plurality of upper channel films 320 may be provided between the plurality of vertical conductive lines 240a and the plurality of third conductive lines 330 and between the plurality of vertical conductive lines 240a and the plurality of fourth conductive lines 340. For example, the plurality of upper gate insulating films 310 may cover the side surfaces of the upper portions of the plurality of vertical conductive lines 240a.

The lower gate structure 160 including the first conductive line 120a and the plurality of gate insulating films 152a provided between the plurality of first conductive lines 120a and the channel structure 140b, and the channel structure 140b, may configure a selection transistor. The first conductive line 120a may be a gate of the selection transistor. The upper gate insulating film 310, the upper channel film 320, the third conductive line 330, the upper portion of the vertical conductive line 240a, and the fourth conductive line 340 may configure a read transistor. The third conductive line 330, the upper portion of the vertical conductive line 240a, and the fourth conductive line 340 may be respectively a drain, a gate, and a source of the read transistor. The channel structure 140b and the gate structure 150a may configure a write transistor. The semiconductor memory device 3 may be 3 Transistor n Capacitor ferroelectric random access memory (3TnC FeRAM) including a plurality of memory cell consisting of the selection transistor, the write transistor, the read transistor, and each of the plurality of ferroelectric capacitors.

FIGS. 14A, 14B and 14C are each an enlarged view showing a portion of a semiconductor memory device. In detail, FIGS. 14A, 14B and 14C are each an enlarged vertical cross-sectional view showing region XIV of FIG. 2A. Among the descriptions presented with reference to FIGS. 14A and 14B, redundant descriptions to those presented with reference to FIGS. 2A and 2B may be omitted.

Referring to FIG. 14A, according to one or more example embodiments, the second conductive line 220 may include the conductive base portion 220B filling the removed space MRS and the conductive protruding portion 220P filling the plurality of dielectric recesses 230R. The ferroelectric pattern 230 may be provided between the second conductive line 220 and the vertical conductive line 240. The ferroelectric pattern 230 may be provided between the side surface of the vertical conductive line 240 and the side surfaces of the plurality of insulating layers 202 and between the side surface of the vertical conductive line 240 and the side surfaces of the plurality of second conductive lines 220. The vertical conductive line 240 may have the electrode recesses 240R corresponding to the second conductive line 220. The electrode recesses 240R may continuously extend two-dimensionally and may surround the vertical conductive line 240. Each of the plurality of electrode recesses 240R may have a concave shape extending into the vertical conductive line 240. The ferroelectric pattern 230 covering the surface of the vertical conductive line 240 in the plurality of electrode recesses 240R may define the plurality of dielectric recesses 230R corresponding to the plurality of electrode recesses 240R. The conductive protruding portion 220P of the second conductive line 220 may have a convex shape extending into the vertical conductive line 240. The conductive base portion 220B may have a first height H1 in the vertical direction (Z direction), and the conductive protruding portion 220P may have a second height H2 as the maximum height in the vertical direction (Z direction). The second height H2 may be greater than the first height H1.

Referring to FIG. 14B, according to one or more example embodiments, the second conductive line 220 may include the conductive base portion 220B filling the removed space MRS and a conductive protruding portion 220Pa filling the plurality of dielectric recesses 230R. The ferroelectric pattern 230 may be provided between the second conductive line 220 and the vertical conductive line 240. The ferroelectric pattern 230 may be provided between the side surface of the vertical conductive line 240 and the plurality of insulating layers 202 and between the side surface of the vertical conductive line 240 and the side surfaces of the plurality of second conductive lines 220. The vertical conductive line 240 may have the electrode recesses 240R corresponding to the second conductive line 220. The electrode recesses 240R may continuously extend two-dimensionally and may surround the vertical conductive line 240. Each of the plurality of electrode recesses 240R may have a concave shape extending into the vertical conductive line 240. The ferroelectric pattern 230 covering the surface of the vertical conductive line 240 in the plurality of electrode recesses 240R may define the plurality of dielectric recesses 230R corresponding to the plurality of electrode recesses 240R. The conductive protruding portion 220Pa of the second conductive line 220 may extend into the vertical conductive line 240 while the height of the conductive protruding portion 220Pa uniformly decreases in the vertical direction (Z direction). For example, the conductive protruding portion 220Pa of the second conductive line 220 may have a triangular vertical cross-section.

Referring to FIG. 14C, according to one or more example embodiments, the second conductive line 220 may include the conductive base portion 220B filling the removed space MRS and a conductive protruding portion 220Pb filling the plurality of dielectric recesses 230R. The ferroelectric pattern 230 may be provided between the second conductive line 220 and the vertical conductive line 240. The ferroelectric pattern 230 may be provided between the side surface of the vertical conductive line 240 and the side surfaces of the plurality of insulating layers 202 and between the side surface of the vertical conductive line 240 and the side surfaces of the plurality of second conductive lines 220. The vertical conductive line 240 may have the electrode recesses 240R corresponding to the second conductive line 220. The electrode recesses 240R may continuously extend two-dimensionally and may surround the vertical conductive line 240. Each of the plurality of electrode recesses 240R may have a concave shape extending into the vertical conductive line 240. The ferroelectric pattern 230 covering the surface of the vertical conductive line 240 in the plurality of electrode recesses 240R may define the plurality of dielectric recesses 230R corresponding to the plurality of electrode recesses 240R. The conductive protruding portion 220Pb of the second conductive line 220 may include a main protruding portion 220PS having a convex shape from the conductive base portion 220B toward the vertical conductive line 240 and a sub-protruding portion 220PL having a convex shape from the main protruding portion 220PS toward the vertical conductive line 240. The conductive protruding portion 220Pb of the second conductive line 220 may have an embossed shape from the main protruding portion 220PS toward the vertical conductive line 240. For example, the conductive protruding portion 220Pb of the second conductive line 220 may include the main protruding portion 220PS extending into the vertical conductive line 240 with a height decrease rate, which increases in the vertical direction (Z direction), and the sub-protruding portion 220PL extending into the vertical conductive line 240 with a height decrease rate, which decreases and then increases in the vertical direction (Z direction). FIG. 14C illustrates that the conductive protruding portion 220Pb includes one main protruding portion 220PS and one sub-protruding portion 220PL, but embodiments of the disclosure are not limited thereto. For example, the conductive protruding portion 220Pb may include one main protruding portion 220PS and a plurality of sub-protruding portions 220PL extending from the one main protruding portion 220PS into the vertical conductive line 240 and spaced apart from each other.

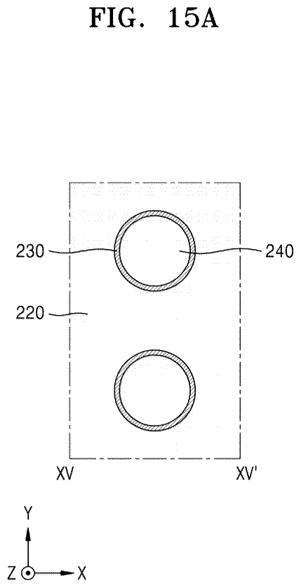

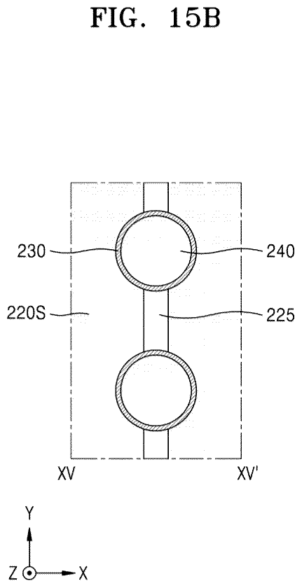

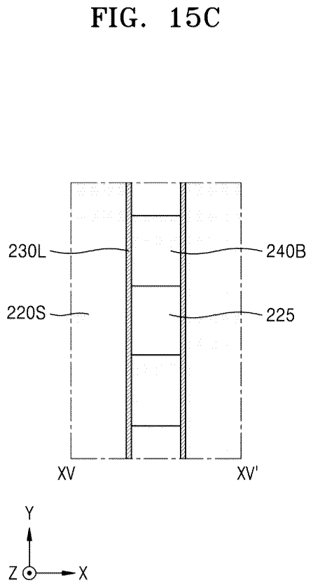

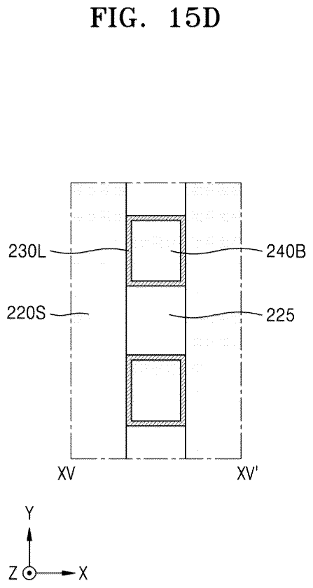

FIGS. 15A, 15B, 15C and 15D are each an enlarged view showing a portion of a semiconductor memory device, according to one or more example embodiments. In detail, FIGS. 15A, 15B, 15C and 15D are each a horizontal cross-sectional view cut along line XV-XV′ of FIG. 14A, according to one or more example embodiments.

Referring to FIG. 15A, according to one or more example embodiments, the vertical conductive line 240 may have a circular horizontal cross-section, but embodiments of the disclosure are not limited thereto. For example, the horizontal cross-section of the vertical conductive line 240 may have a square shape, a rectangular shape, a circular shape, an oval shape, or a polygonal shape greater than four sides. The horizontal width of the vertical conductive line 240 in the first horizontal direction (X direction) may be less than the horizontal width of the second conductive line 220 in the first horizontal direction (X direction). The ferroelectric pattern 230 may be provided between the second conductive line 220 and the vertical conductive line 240. The ferroelectric pattern 230 may continuously extend two-dimensionally and may surround the vertical conductive line 240. For example, when the vertical conductive line 240 has a circular horizontal cross-section, the ferroelectric pattern 230 may have a horizontal cross-section of a circular ring shape. The second conductive line 220 may continuously extend two-dimensionally and may surround the vertical conductive line 240 with the ferroelectric pattern 230 therebetween.

Referring to FIG. 15B, according to one or more example embodiments, a plurality of second conductive lines 220S may extend in the second horizontal direction (Y direction) while being spaced apart from each other in each of the first horizontal direction (X direction) and the vertical direction (Z direction). The ferroelectric pattern 230 may continuously extend two-dimensionally and may surround the vertical conductive line 240. The plurality of second conductive lines 220S may be spaced apart from each other in the first horizontal direction (X direction) with respect to the vertical conductive line 240 and the ferroelectric pattern 230 surrounding the vertical conductive line 240. A pair of second conductive lines 220S spaced apart from each other in the first horizontal direction (X direction) with respect to the vertical conductive line 240 and the ferroelectric pattern 230 surrounding the vertical conductive line 240 shown in FIG. 15B may have a shape of the second conductive line 220 shown in FIG. 15A divided into two. A line separating insulation layer 225 may be provided between the pair of second conductive lines 220S spaced apart from each other in the first horizontal direction (X direction) with respect to the vertical conductive line 240 and the ferroelectric pattern 230 surrounding the vertical conductive line 240. The line separating insulation layer 225 may include silicon oxide, silicon nitride, silicon oxynitride, silicon carbide, silicon carbon nitride, an insulating material having a lower permittivity than that of silicon oxide, or a combination thereof.

Among the pair of second conductive lines 220S spaced apart from each other in the first horizontal direction (X direction) with respect to the vertical conductive line 240 and the ferroelectric pattern 230 surrounding the vertical conductive line 240, one second conductive line 220S, the vertical conductive line 240, and a portion of the ferroelectric pattern 230 provided between the one second conductive line 220S and the vertical conductive line 240 may configure a separate ferroelectric capacitor, and another second conductive line 220S, the vertical conductive line 240, and a portion of the ferroelectric pattern 230 provided between the another second conductive line 220S and the vertical conductive line 240 may configure a separate ferroelectric capacitor. For example, when the plurality of second conductive lines 220 included in the semiconductor memory device 1 shown in FIGS. 2A and 2B are replaced with the plurality of second conductive lines 220S shown in FIG. 15B, the number of ferroelectric capacitors CFE included in one memory cell MC may increase twice, and thus, information that may be stored in one memory cell MC may increase. To distinguish the second conductive line 220 shown in FIG. 15B from the second conductive line 220 shown in FIGS. 2A and 2B, the second conductive line 220 shown in FIG. 15B may be referred to as a sub-conductive line. For example, the vertical conductive line 240 and the ferroelectric pattern 230 surrounding the vertical conductive line 240 may be provided between a pair of the sub-conductive lines spaced apart from each other in the first horizontal direction (X direction).

Referring to FIG. 15C, according to one or more example embodiments, a vertical conductive line 240B may have a quadrangular horizontal cross-section. The plurality of second conductive lines 220S may extend in the second horizontal direction (Y direction) while being spaced apart from each other in each of the first horizontal direction (X direction) and the vertical direction (Z direction). The plurality of second conductive lines 220S may be apart from each other in the first horizontal direction (X direction) with respect to the vertical conductive line 240B. A ferroelectric pattern 230L may be provided between the second conductive line 220S and the vertical conductive line 240B. The ferroelectric pattern 230L may extend two-dimensionally in the second horizontal direction (Y direction) along the side surface of the second conductive line 220S toward the vertical conductive line 240B. For example, among the side surfaces of the vertical conductive line 240B, while side surfaces that face the ferroelectric pattern 230L, that is, side surfaces that face the first horizontal direction (X direction), may be covered by the ferroelectric pattern 230L, and side surfaces that do not face the ferroelectric pattern 230L, that is, side surfaces that face the second horizontal direction (Y direction), may not be covered by the ferroelectric pattern 230L.

Referring to FIG. 15D, according to one or more example embodiments, the vertical conductive line 240B may have a quadrangular horizontal cross-section. The plurality of second conductive lines 220S may extend in the second horizontal direction (Y direction) while being spaced apart from each other in each of the first horizontal direction (X direction) and the vertical direction (Z direction). The plurality of second conductive lines 220S may be spaced apart from each other in the first horizontal direction (X direction) with respect to the vertical conductive line 240B. The ferroelectric pattern 230L may be provided between the second conductive line 220S and the vertical conductive line 240B. The ferroelectric pattern 230L may continuously extend two-dimensionally and may surround the vertical conductive line 240B. For example, when the vertical conductive line 240B has a quadrangular horizontal cross-section, the ferroelectric pattern 230L may have a quadrangular ring-shaped horizontal cross-section.

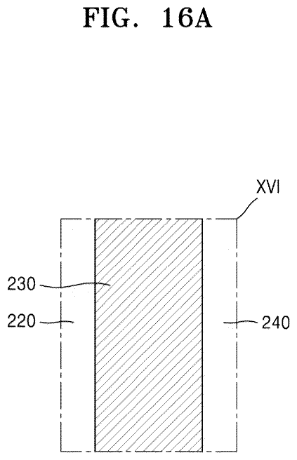

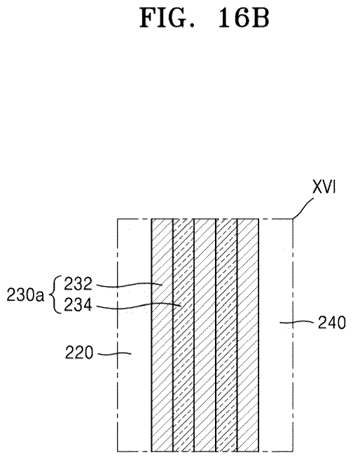

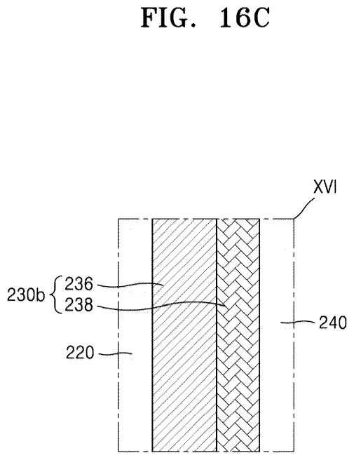

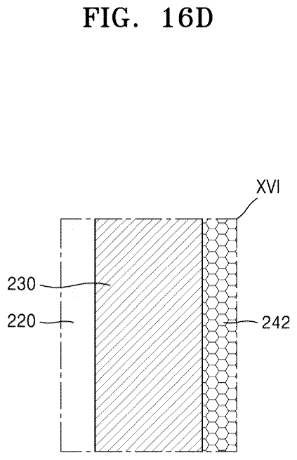

FIGS. 16A, 16B, 16C and 16D are each an enlarged view showing a portion of a semiconductor memory device according to one or more example embodiments. In detail, FIGS. 16A, 16B, 16C and 16D are each an enlarged vertical cross-sectional view showing region XVI of FIG. 14A. In FIGS. 16A, 16B, 16C and 16D, rounded boundaries of the second conductive line 220, the ferroelectric pattern 230, and the vertical conductive line 240 are illustrated as straight lines for convenience of illustration.

Referring to FIG. 16A, according to one or more example embodiments, the ferroelectric pattern 230 may be provided between the second conductive line 220 and the vertical conductive line 240. The ferroelectric pattern 230 may be formed in a single film. For example, a ferroelectric capacitor consisting of the second conductive line 220, the vertical conductive line 240, and the ferroelectric pattern 230 may perform a symmetrical operation. In one or more example embodiments, the second conductive line 220 and the vertical conductive line 240 may include the same material. For example, the second conductive line 220 and the vertical conductive line 240 may include a conductive material having the same work function.

Referring to FIG. 16B, according to one or more example embodiments, a ferroelectric pattern 230a may be provided between the second conductive line 220 and the vertical conductive line 240. The ferroelectric pattern 230a may be formed in a multilayer film. The ferroelectric pattern 230a may include at least one first dielectric layer 232 and at least one second dielectric layer 234. For example, the ferroelectric pattern 230a may include a plurality of the first dielectric layers 232 and a plurality of the second dielectric layers 234 which are alternately arranged between the second conductive line 220 and the vertical conductive line 240. In one or more example embodiments, the first dielectric layer 232 and the second dielectric layer 234 may include different types of ferroelectric materials. In one or more example embodiments, one of the first dielectric layer 232 and the second dielectric layer 234 may include a ferroelectric material, and the other may include a dielectric material that does not exhibit ferroelectricity. A ferroelectric capacitor consisting of the second conductive line 220, the vertical conductive line 240, and the ferroelectric pattern 230a may perform a symmetrical operation.

Referring to FIG. 16C, according to one or more example embodiments, a ferroelectric pattern 230b may be provided between the second conductive line 220 and the vertical conductive line 240. The ferroelectric pattern 230b may be formed in a multilayer film. The ferroelectric pattern 230a may include a ferroelectric layer 236 and an oxide semiconductor layer 238. The ferroelectric layer 236 may include a ferroelectric material, and the oxide semiconductor layer 238 may include an oxide semiconductor material. A ferroelectric capacitor consisting of the second conductive line 220, the vertical conductive line 240, and the ferroelectric pattern 230b may perform a symmetrical operation.

Referring to FIG. 16D, according to one or more example embodiments, the ferroelectric pattern 230 may be provided between the second conductive line 220 and a vertical conductive line 242. In one or more example embodiments, the second conductive line 220 and the vertical conductive line 242 may include different materials. For example, the second conductive line 220 and the vertical conductive line 242 may include conductive materials having different work functions. A ferroelectric capacitor consisting of the second conductive line 220, the vertical conductive line 242, and the ferroelectric pattern 230 may perform a symmetrical operation.

While example embodiments have been particularly shown and described above, it will be apparent to those skilled in the art that various changes in form and details may be made therein without departing from the spirit and scope of the following claims.

What is claimed is:

1. A semiconductor memory device comprising:
a substrate;
a first conductive line on the substrate;
a channel structure on the first conductive line;
a gate structure comprising:
a gate electrode on the first conductive line; and
a gate insulating film between the gate electrode and the channel structure;
a plurality of second conductive lines on the channel structure and the gate structure, and spaced apart from each other in a vertical direction;
a vertical conductive line on the channel structure, extending in the vertical direction, and penetrating the plurality of second conductive lines; and
a ferroelectric pattern between each of the plurality of second conductive lines and the vertical conductive line,
wherein the vertical conductive line comprises a plurality of electrode recesses corresponding to the plurality of second conductive lines and extending into the vertical conductive line, and
wherein portions of the ferroelectric pattern and portions of the plurality of second conductive lines fill the plurality of electrode recesses.

2. The semiconductor memory device of claim 1, wherein each electrode recess of the plurality of electrode recesses continuously extends two-dimensionally and surrounds the vertical conductive line.

3. The semiconductor memory device of claim 1, wherein each second conductive line of the plurality of second conductive lines comprises a conductive base portion and a conductive protruding portion,
wherein each conductive protruding portion fills a corresponding electrode recess of the plurality of electrode recesses, and
wherein a maximum height of the conductive protruding portion in the vertical direction is greater than a maximum height of the conductive base portion in the vertical direction.

4. The semiconductor memory device of claim 1, wherein each electrode recess of the plurality of electrode recesses has a concave shape extending into the vertical conductive line.

5. The semiconductor memory device of claim 4, wherein each second conductive line of the plurality of second conductive lines comprises a conductive base portion and a conductive protruding portion,
wherein each conductive protruding portion fills a corresponding electrode recess of the plurality of electrode recesses, and
wherein the conductive protruding portion has a convex shape extending into the vertical conductive line.

6. The semiconductor memory device of claim 1, wherein each electrode recess of the plurality of electrode recesses extends into the vertical conductive line with a height uniformly decreasing in the vertical direction.

7. The semiconductor memory device of claim 1, wherein the channel structure and the gate structure configure a vertical channel transistor.

8. The semiconductor memory device of claim 1, wherein each second conductive line of the plurality of second conductive lines comprises a pair of sub-conductive lines that are spaced apart from each other in a horizontal direction.

9. The semiconductor memory device of claim 8, wherein the ferroelectric pattern continuously extends two-dimensionally and surrounds the vertical conductive line.

10. The semiconductor memory device of claim 8, wherein the ferroelectric pattern extends two-dimensionally along each of side surfaces of the pair of sub-conductive lines facing the vertical conductive line.

11. A semiconductor memory device comprising:
a plurality of first conductive lines extending in a first horizontal direction and spaced apart from each other in a second horizontal direction orthogonal to the first horizontal direction;
a plurality of channel structures extending in a vertical direction and arranged in columns on the plurality of first conductive lines in each of the first horizontal direction and the second horizontal direction;
a plurality of gate structures comprising:
a plurality of gate lines on the plurality of first conductive lines, spaced apart from each other in the first horizontal direction, and extending in the second horizontal direction; and
a plurality of gate insulating films between the plurality of gate lines and the plurality of channel structures and surrounding at least a portion of side surfaces of the plurality of channel structures;
a plurality of second conductive lines on the plurality of channel structures, spaced apart from each other in each of the first horizontal direction and the vertical direction, and extending in the second horizontal direction;
a plurality of vertical conductive lines on the plurality of channel structures, extending in the vertical direction, and penetrating the plurality of second conductive lines; and
a plurality of ferroelectric patterns between the plurality of second conductive lines and the plurality of vertical conductive lines,
wherein each vertical conductive line of the plurality of vertical conductive lines comprises a plurality of electrode recesses corresponding to second conductive lines spaced apart from each other in the vertical direction,
wherein each vertical conductive line of the plurality of vertical conductive lines penetrates a corresponding conductive line of the plurality of second conductive lines,
wherein portions of the plurality of ferroelectric patterns which cover surfaces of the plurality of vertical conductive lines within the plurality of electrode recesses define a plurality of dielectric recesses, and
wherein the plurality of second conductive lines comprises a plurality of conductive base portions and a plurality of conductive protruding portions that fill the plurality of dielectric recesses.

12. The semiconductor memory device of claim 11, wherein a maximum height of each conductive protruding portion of the plurality of conductive protruding portions in the vertical direction is greater than a maximum height of each conductive base portion of the plurality of conductive base portions in the vertical direction.

13. The semiconductor memory device of claim 11, wherein each electrode recess of the plurality of electrode recesses has a concave shape extending into a corresponding vertical conductive line of the plurality of vertical conductive lines, continuously extends two-dimensionally, and surrounds the corresponding vertical conductive line of the plurality of vertical conductive lines.

14. The semiconductor memory device of claim 11, wherein each conductive protruding portion of the plurality of conductive protruding portions has a convex shape extending into a corresponding vertical conductive line of the plurality of vertical conductive lines.

15. The semiconductor memory device of claim 11, wherein each channel structure of the plurality of channel structures comprises a first impurity area, a channel region, and a second impurity area, which are sequentially arranged in the vertical direction,
wherein the first impurity area contacts one of the plurality of first conductive lines, and
wherein the second impurity area contacts one of the plurality of vertical conductive lines.

16. The semiconductor memory device of claim 11, further comprising:
a third conductive line on the plurality of second conductive lines and extending in the first horizontal direction;
a fourth conductive line on the third conductive line and extending in the second horizontal direction;
an upper gate insulating layer; and
an upper channel film,
wherein each vertical conductive line of the plurality of vertical conductive lines extends in the vertical direction and penetrates the third conductive line and the fourth conductive line,
wherein the upper gate insulating layer covers a side surface of an upper portion of each vertical conductive line of the plurality of vertical conductive lines that penetrates the third conductive line and the fourth conductive line, and
wherein the upper channel film is provided between each vertical conductive line of the plurality of vertical conductive lines and the third conductive line and between each vertical conductive line of the plurality of vertical conductive lines and the fourth conductive line.

17. The semiconductor memory device of claim 11, wherein the plurality of channel structures extend in the vertical direction and penetrate the plurality of first conductive lines, and
wherein the plurality of gate insulating films are provided between the plurality of gate lines and the plurality of channel structures and between the plurality of first conductive lines and the plurality of channel structures.

18. A semiconductor memory device comprising:
a substrate;
a plurality of first conductive lines on the substrate, extending in a first horizontal direction, and spaced apart from each other in a second horizontal direction orthogonal to the first horizontal direction;
a plurality of channel structures arranged on the plurality of first conductive lines in columns in each of the first horizontal direction and the second horizontal direction,
wherein each channel structure of the plurality of channel structures comprises a first impurity area, a channel region, and a second impurity area, which are sequentially arranged in a vertical direction, and
wherein the first impurity area contacts one of the plurality of first conductive lines;
a plurality of gate structures comprising:
a plurality of gate lines on the plurality of first conductive lines, spaced apart from each other in the first horizontal direction, and extending in the second horizontal direction; and
a plurality of gate insulating films provided between the plurality of gate lines and one of the plurality of channel structures and surrounds at least a portion of a side surface of one of the plurality of channel structures;
a plurality of second conductive lines on the plurality of channel structures, spaced apart from each other in each of the first horizontal direction and the vertical direction, and extending in the second horizontal direction;
a plurality of vertical conductive lines respectively contacting the second impurity areas, extending in the vertical direction, and penetrating the plurality of second conductive lines; and
a plurality of ferroelectric patterns provided between the plurality of second conductive lines and the plurality of vertical conductive lines,
wherein each vertical conductive line of the plurality of vertical conductive lines comprises a plurality of electrode recesses corresponding to second conductive lines spaced apart from each other in the vertical direction,
wherein each vertical conductive line of the plurality of vertical conductive lines penetrates a corresponding second conductive line of the plurality of second conductive lines and extends two-dimensionally,
wherein each of plurality of electrode recesses surrounds a corresponding vertical conductive line of the plurality of vertical conductive lines,
wherein portions of the plurality of ferroelectric patterns which cover surfaces of the plurality of vertical conductive lines within the plurality of electrode recesses define a plurality of dielectric recesses, and
wherein each of the plurality of second conductive lines comprises:
a conductive base portion having a first maximum height; and
a conductive protruding portion having a second maximum height greater than the first maximum height and filling a corresponding dielectric recess of the plurality of dielectric recesses.

19. The semiconductor memory device of claim 18, wherein the channel structure comprises an oxide semiconductor material,
wherein the first impurity area and the second impurity area are injected with same conductive impurities, and
wherein the channel region is an intrinsic semiconductor.

20. The semiconductor memory device of claim 18, wherein each electrode recess of the plurality of electrode recesses has a concave shape extending into a corresponding vertical conductive line of the plurality of vertical conductive lines, and
wherein the conductive protruding portion of each second conductive line of the plurality of second conductive lines has a convex shape extending into a corresponding one of the plurality of vertical conductive lines.
